(19) United States
(12) Patent Application Publication
(10) Pub. No.: US 2024/0373712 A1
(43) Pub. Date: Nov. 7, 2024

(54) LIGHT EMITTING DEVICE AND ELECTRONIC APPARATUS

(71) Applicant: Sony Semiconductor Solutions Corporation, Kanagawa (JP)

(72) Inventors: Yoshinori Uchida, Kanagawa (JP); Tomoaki Sawabe, Kanagawa (JP)

(21) Appl. No.: 18/567,154

(22) PCT Filed: Mar. 25, 2022
(86) PCT No.: PCT/JP22/14279

§ 371 Date: Dec. 5, 2023

(30) Foreign Application Priority Data
Jul. 9, 2021 (JP) 2021-114348

(51) Int. Cl. H10K 59/35; H10K 50/13; H10K 59/38; H10K 59/80

(52) U.S. Cl. CPC H10K 59/353; H10K 50/13; H10K 59/876; H10K 59/38

(57) ABSTRACT

A light emitting device having superior luminance and an electronic apparatus using the light emitting device are provided.

A light emitting device includes: a first subpixel; and a second subpixel and a third subpixel of which color types are different from that of the first subpixel, in which the first subpixel and the second subpixel have a first light emitting layer emitting light of a predetermined color type, and the third subpixel has a second light emitting layer that is stacked on the first light emitting layer and has a light emission color different from that of the first light emitting layer.

### TECHNICAL FIELD

The present disclosure relates to a light emitting device and an electronic apparatus.

### BACKGROUND ART

Light emitting devices having a light emitting layer such as display devices and the like are used in various fields such as augmented reality (AR) and virtual reality (VR). As the light emitting devices, light emitting devices formed using a scheme in which a light emitting layer separated for each subpixel is provided and light emitting devices formed using a scheme in which a color filter according to a subpixel and a white light emitting layer common to subpixels are provided are known. In addition, as disclosed in PTL 1, light emitting devices in which light emitting layers separated for respective subpixels are stacked are known.

### CITATION LIST

### Patent Literature

### PTL 1

JP 2010-27595 A

### SUMMARY

### Technical Problem

In the light emitting device as disclosed in PTL 1, there is room for improvement from the point of view of improvement of luminance.

The present disclosure is in consideration of the points described above, and one object thereof is to provide a light emitting device having superior luminance and an electronic apparatus using the light emitting device.

### Solution to Problem

The present disclosure, for example, is (1) a light emitting device including: a first subpixel; and a second subpixel and a third subpixel of which color types are different from that of the first subpixel, in which the first subpixel and the second subpixel have a first light emitting layer emitting light of a predetermined color type, and the third subpixel has a second light emitting layer that is stacked on the first light emitting layer and has a light emission color different from that of the first light emitting layer.

The present disclosure, for example, may be (2) an electronic apparatus including the display device described in (1) above.

### BRIEF DESCRIPTION OF DRAWINGS

FIG. 1 is a cross-sectional view for describing an example of a display device according to a first embodiment.

FIG. 2A is a plan view for describing an example of a display device. FIGS. 2B and 2C are plan views illustrating a layout of a subpixel in an area XS surrounded by a broken line in FIG. 2A.

FIG. 3A is a cross-sectional view for describing an example of a first light emitting layer of a display device according to the first embodiment. FIG. 3B is a cross-sectional view for describing an example of a first light emitting layer according to a modified example of a display device according to the first embodiment.

FIG. 4 is a cross-sectional view for describing an example of a display device according to the first embodiment.

FIG. 5 is a plan view for describing an electrode structure of a display device according to the first embodiment.

FIGS. 6A and 6B are cross-sectional views for describing a method of manufacturing a display device according to the first embodiment.

FIGS. 7A and 7B are cross-sectional views for describing a method of manufacturing a display device according to the first embodiment.

FIGS. 8A and 8B are cross-sectional views for describing a method of manufacturing a display device according to the first embodiment.

FIGS. 9A and 9B are cross-sectional views for describing a method of manufacturing a display device according to the first embodiment.

FIGS. 10A and 10B are cross-sectional views for describing a method of manufacturing a display device according to the first embodiment.

FIG. 11 is a diagram for describing a light extracting mechanism of a pixel of a display device according to the first embodiment.

FIG. 12 is a table for describing a modified example of a display device according to the first embodiment.

FIGS. 13A and 13B are plan views illustrating one example of a layout of a subpixel of a display device according to the first embodiment.

FIG. 14 is a plan view for describing a modified example of a display device according to the first embodiment.

FIG. 15 is a cross-sectional view for describing an example of a display device according to a second embodiment.

FIG. 16 is a cross-sectional view for describing an example of a display device according to a third embodiment.

FIGS. 17A and 17B are main-part cross-sectional views for describing an example of a resonator structure in a display device according to the third embodiment.

FIG. 18 is a cross-sectional view for describing an example of a display device according to a fourth embodiment.

FIG. 19 is a cross-sectional view for describing an example of a display device according to a fifth embodiment.

FIG. 20 is a cross-sectional view for describing an example of a display device according to a sixth embodiment.

FIG. 21 is a diagram for describing a light extracting mechanism of a pixel of a display device according to the sixth embodiment.

FIG. 22 is a cross-sectional view for describing an example of a display device according to the sixth embodiment.

FIGS. 23A and 23B are diagrams for describing an example of an electronic apparatus in which the display device is used.

FIG. 24 is a diagram for describing an example of the electronic apparatus in which the display device is used.

FIG. 25 is a diagram for describing an example of the electronic apparatus in which the display device is used.

### DESCRIPTION OF EMBODIMENTS

An example according to the present disclosure will be described below with reference to the drawings. The description will be made in the order below. In the present specification and the drawings, configurations having substantially the same functional configuration are denoted by the same reference numerals, and repeated descriptions thereof are omitted.

Also, the description will be given in the following order.
1. First embodiment
2. Second embodiment
3. Third embodiment
4. Fourth embodiment
5. Fifth embodiment
6. Sixth embodiment
7. Electronic Apparatus
8. Lighting Device

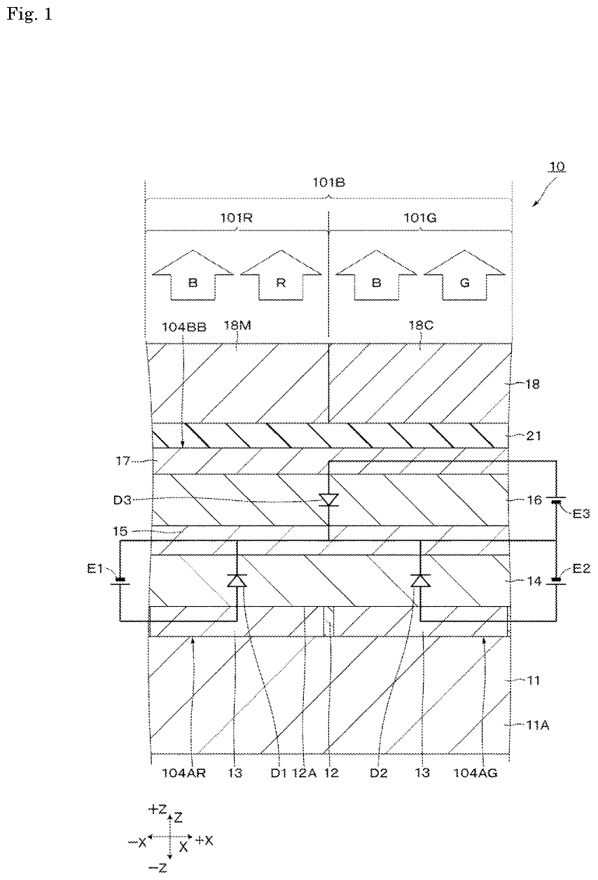

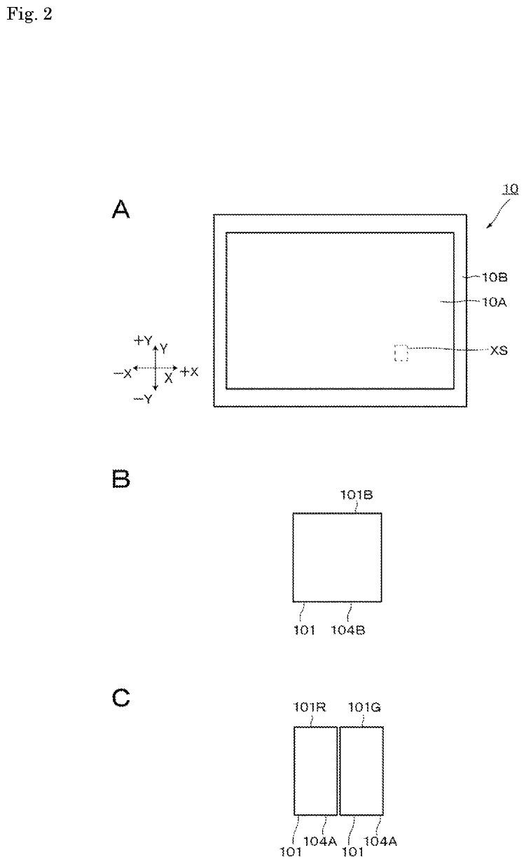

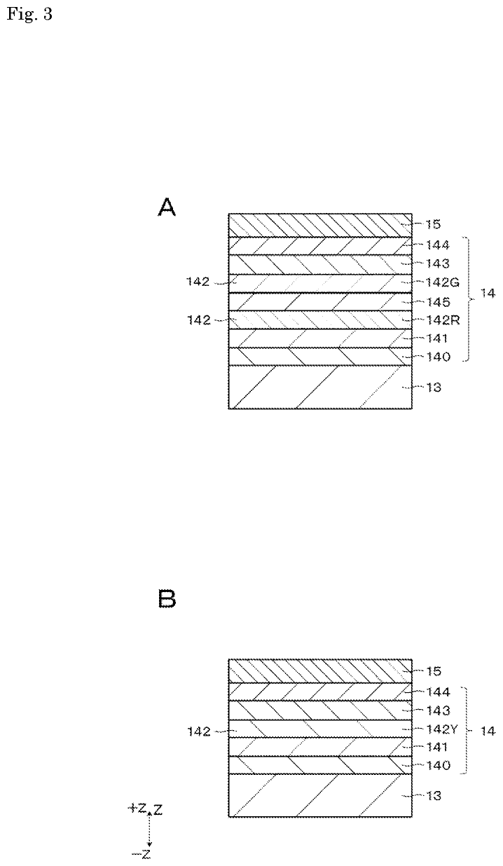

The following description is an appropriate specific example of the present disclosure, and details of the present disclosure are not limited to these embodiments and the like. For convenience of explanation, longitudinal, horizontal, and vertical directions are indicated in the following description but the details of the present disclosure are not limited by these directions. In the examples of FIGS. 1 and 2, a Z-axis direction is the vertical direction (a +Z direction extends upward and a −Z direction extends downward), an X-axis direction is the longitudinal direction (a +X direction extends forward and a −X direction extends rearward), and a Y-axis direction is the horizontal direction (a +Y direction extends to the right and a −Y direction extends to the left), and the description will be presented on the basis of these directions. The same applies to FIGS. 3 to 22. The relative proportions of the sizes and thicknesses of layers illustrated in the drawings including FIG. 1 are described for convenience. Actual proportions are not limited thereto. The same applies to FIGS. 2 to 22 regarding the definitions of these directions and the proportions.

A light emitting device according to the present disclosure, for example, is a display device, a lighting device, or the like. In the following first to sixth embodiments, a case in which a light emitting device is a display device will be described.

### First Embodiment

### 1-1 Configuration of Display Device

An organic electroluminescene (EL) display device 10 (hereinafter, simply referred to as “display device 10”) will be described below as an example of a display device according to an embodiment of the present disclosure. FIG. 1 is a cross-sectional view illustrating one configuration example of the display device 10. The display device 10 includes a drive substrate 11 and a plurality of light emitting elements 104A and 104B. In FIG. 1, for the convenience of description, illustration of a filling resin layer and a counter substrate to be described below are omitted. This similarly applies to FIGS. 2 to 22.

The display device 10 is a display device of a top emission type. In the display device 10, the drive substrate 11 is positioned on a rear face side of the display device 10, and a direction (+Z direction) from the drive substrate 11 to the light emitting element 104 is a direction of a front face side (a display face side of a display area 10A; an upper face side) of the display device 10. In the following description, in each layer configuring the display device 10, a face that is a display face side of the display area 10A of the display device 10 will be referred to as a first face (an upper face), and a face that is a rear face side of the display device 10 will be referred to as a second face (a lower face).

### Configuration of Subpixel

In the example of the display device 10 illustrated in FIG. 1, one pixel is formed using a combination of a plurality of subpixels corresponding to a plurality of color types. In a plurality of pixels disposed in the display device 10, in the example of FIG. 1, one pixel has a combination of a first subpixel, a second subpixel, and a third subpixel. In addition, the first subpixel, the second subpixel, and the third subpixel are subpixels corresponding to predetermined color types among a plurality of color types. In this example, three colors of red, green, and blue are set as the plurality of color types, and three types including a subpixel 101R as the first subpixel, a subpixel 101G as the second subpixel, and a subpixel 101B as the third subpixel are disposed. In the first embodiment, in a case in which a combination of the three types of subpixels described above is used is described as an example, the first subpixel may be referred to as a subpixel 101R, the second subpixel may be referred to as a subpixel 101G, and the third subpixel may be referred to as a subpixel 101B. This also applies to a second embodiment to a sixth embodiment. The subpixel 101R, the subpixel 101G, and the subpixel 101B are respectively a red subpixel, a green subpixel, and a blue subpixel and respectively perform display of red, green, and blue with red, green, and blue set as light emission colors. However, the example illustrated in FIG. 1 is one example and the color types of the plurality of subpixels are not limited. In addition, wavelengths of light corresponding to the color types of red, green, and blue, for example, can be respectively set as wavelengths in the range of 610 nm to 650 nm, the range of 510 nm to 590 nm, and the range of 440 nm to 480 nm. In addition, in the example illustrated in FIGS. 2B and 2C, a layout of the subpixels 101R, 101G, and 101B is a layout in which the subpixels 101R and 101G have strip forms (a layout of a strip form), and the subpixel 101B has a shape covering both the subpixel 101R and the subpixel 101G (in the example illustrated in FIG. 1, a square shape). Thus, in the example illustrated in FIGS. 2B and 2C, a size of the subpixel 101B is larger than a size of each of the subpixels 101R and 101G. The combination of the subpixels 101R, 101G, and 101B is two-dimensionally disposed in a matrix pattern in a direction in which the display area 10A expands. FIG. 2B is a diagram for describing a state in which the subpixel 101B of an area of a part of the inside of display formed in the display area 10A illustrated in FIG. 2A is enlarged. FIG. 2C is a diagram for describing a state in which the subpixels 101R and 101G configuring one pixel together with the subpixel 101B illustrated in FIG. 2B are enlarged. FIG. 2A is a diagram for describing the display area 10A of the display device 10 according to the first embodiment. In addition, in FIG. 2A, reference sign 10B represents an outer side part of the display area 10A.

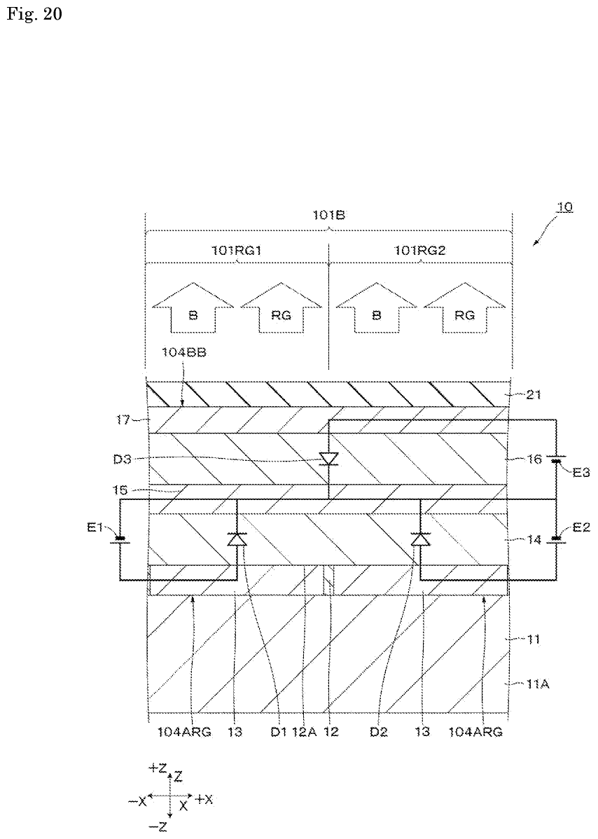

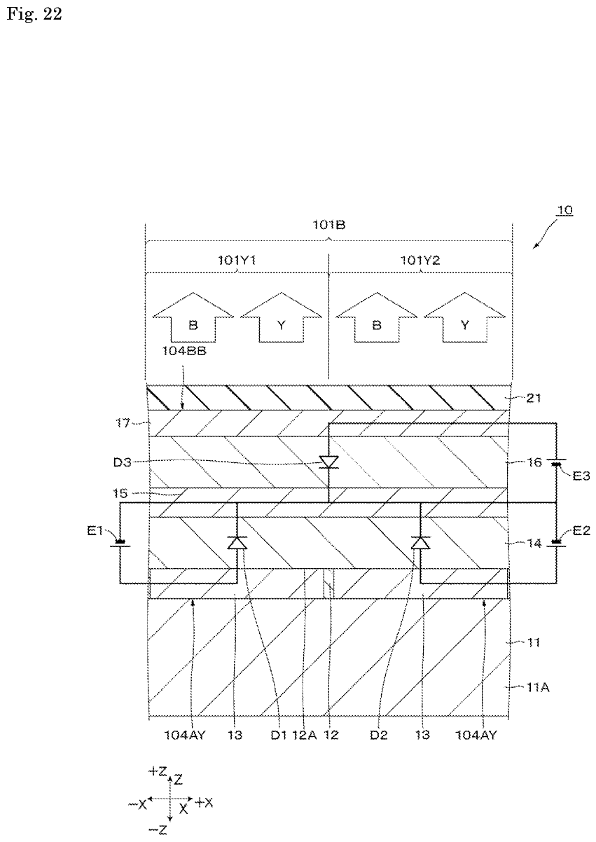

In FIG. 1, although thick arrows in which R, G, and B are disposed inside on a first face side are illustrated in accordance with illustration of the subpixels 101R, 101G, and 101B, these represent color types of light emitted from a display face of the display device from respective positions. For example, a thick arrow in which the letter “R” is disposed represents that red light is emitted, a thick arrow in which the letter “G” is disposed represents that green light is emitted, and a thick arrow in which the letter “B” is disposed represents that blue light is emitted, This similarly applies to FIGS. 2 to 22. In addition, in FIGS. 20 and 22, a thick arrow in which the letter “Y” is disposed represents that yellow light is emitted, and a thick arrow in which the letters “RG” are disposed represents that light in which red light and green light are put together is emitted.

In the following description, in a case in which the subpixels 101R, 101G, and 101B do not need to be distinguished from each other, the subpixels 101R, 101G, and 101B will be collectively referred to as a subpixel 101. This similarly applies to the second embodiment to the sixth embodiment.

### Drive Substrate

In the drive substrate 11, various circuits driving a plurality of light emitting elements (light emitting elements 104A and 104B) are disposed in a substrate 11A. Examples of various circuits include a drive circuit controlling driving of the light emitting elements (the light emitting elements 104A and 104B), a power supply circuit (not illustrated) supplying electric power to the plurality of light emitting elements.

The substrate 11A may be made of, for example, glass or resin having low moisture and oxygen permeability, or may be made of a semiconductor that facilitates the formation of transistors and the like. Specifically, the substrate 11A may be a glass substrate, a semiconductor substrate, a resin substrate, or the like. The glass substrate includes, for example, high strain-point glass, soda glass, borosilicate glass, forsterite, lead glass, or quartz glass. The semiconductor substrate includes, for example, amorphous silicon, polycrystalline silicon, monocrystalline silicon, or the like. A resin substrate contains, for example, at least one selected from the group consisting of polymethyl methacrylate, polyvinyl alcohol, polyvinyl phenol, polyethersulfone, polyimide, polycarbonate, polyethylene terephthalate, and polyethylene naphthalate.

On a first face of the drive substrate 11, a plurality of contact plugs (not illustrated) are disposed. The contact plugs connect the light emitting element 104A and the light emitting element 104B and various circuits disposed in the substrate 11A.

### Light Emitting Element

In the display device 10, on the first face of the drive substrate 11, a plurality of light emitting elements are disposed. In the examples illustrated in FIGS. 1 and 2 and the like, the light emitting elements are organic electroluminescence elements. In addition, in this example, a plurality of light emitting elements are included in one pixel, and the light emitting element 104A and the light emitting element 104B are included as the plurality of light emitting elements. The light emitting element 104A is formed in the subpixels 101R and 101G. A part of the light emitting element 104A that corresponds to the subpixel 101R will be referred to as a light emitting element 104AR. A part of the light emitting element 104A that corresponds to the subpixel 101G will be referred to as a light emitting element 104AG. In addition, the light emitting element 104B is formed in the subpixel 101B. Particularly, in a case in which it is the light emitting element 104B corresponding to the subpixel 101B is to be specified, it will be referred to as a light emitting element 104BB. In addition, in a case in which the light emitting elements 104AR, 104AG, and 104BB do not need to be distinguished from each other, the light emitting elements 104AR, 104AG, and 104BB will be collectively referred to as a light emitting element 104.

A layout of the light emitting element 104A is a layout according to the subpixels 101R and 101G. A layout of the light emitting element 104B is a layout according to the subpixel 101B. In the examples illustrated in FIGS. 1 and 2 and the like, a size of the subpixel 101B is larger (wider) than a size of each of the subpixels 101R and 101G. In one pixel, in a plan view of the display area 10A, a formation area of the light emitting element 104BB is larger than any area of formation parts of the light emitting element 104AR and 104AG. For this reason, in the size of a light emission area of the subpixel 101 per pixel, a state in which the size of a light emission area of the subpixel 101B according to the light emitting element 104B is larger than the size of a light emission area of the subpixel 101R according to the light emitting element 104A (the light emitting element 104AR) can be formed. In addition, a state in which the size of a light emission area of the subpixel 101B according to the light emitting element 104B is larger than the size of a light emission area of the subpixel 101G according to the light emitting element 104A (the light emitting element 104AG) can be formed.

The light emitting element 104A includes a first electrode 13, a first light emitting layer 14, and a second electrode 15. Thus, the subpixel 101R and 101G include the first electrode 13, the first light emitting layer 14, and the second electrode 15. In the example illustrated in FIG. 1, the first electrode 13, the first light emitting layer 14, and the second electrode 15 are stacked in order in a direction from a second face to a first face (in order from a side closest to the drive substrate 11) (in a +Z-axis direction). The first electrode 13 and the second electrode 15 form one pair of electrodes that applies an electric field to the first light emitting layer 14.

The light emitting element 104B includes a second light emitting layer 16 and a third electrode 17 and, as will be described below, has the second electrode 15 to be common together with the light emitting element 104A. Thus, the subpixel 101B includes the third electrode 17 and the second light emitting layer 16 and has the second electrode 15 to be common together with the light emitting element 104A. In the example illustrated in FIG. 1, the second electrode 15, the second light emitting layer 16, and the third electrode 17 are stacked in order in a direction from the second face to the first face. The second electrode 15 and the third electrode 17 form one pair of electrodes that applies an electric field to the second light emitting layer 16.

### First Electrode

A plurality of first electrodes 13 are disposed on the first face side of the drive substrate 11. The first electrode 13 is electrically separated from an insulating layer 12 to be described below for each subpixel 101. In the example illustrated in FIG. 1, the first electrode 13 is electrically separated in accordance with the layout of the subpixel 101R as the first subpixel and the subpixel 101G as the second subpixel.

The first electrode 13 is an anode electrode. In the example illustrated in FIG. 1, it is appropriate that the first electrode 13 also has a function as a reflective layer. In this case, it is preferable that the reflectivity of the first electrode 13 be high as possibly. In addition, it is preferable that the first electrode 13 be configured using a material having a high work function from the aspect of raising light emission efficiency.

The first electrode 13 is configured using at least one layer out of a metal layer and a metal oxide layer. The first electrode 13 may be configured using a single layer film of a metal layer or a metal oxide layer or a laminated film of a metal layer and a metal oxide layer. In a case in which the first electrode 13 is configured using a laminated film, although the metal oxide layer may be disposed on the first light emitting layer 14 side, and the metal layer may be disposed on the first light emitting layer 14 side, from the point of view of forming a layer having a high work function to be adjacent to the first light emitting layer 14, it is preferable that the metal oxide layer be disposed on the first light emitting layer 14 side.

From the point of view of reliably having a function as a reflective layer, the first electrode 13 may be formed in a reflective plate and a transparent conductive layer. For example, this can be realized by using a metal layer having light reflectivity as a reflective plate and a metal oxide film having light permeability as a transparent conductive layer. This does not regulate arrangement of a layer having a function as a reflective layer separately from the first electrode 13. In other words, the first electrode 13 may be formed in a transparent conductive layer, and a reflective layer may be disposed separately from the first electrode 13.

The metal layer contains, for example, at least one metallic element selected from the group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may contain the at least one metallic element as a constituent element of an alloy. Specific examples of alloys include aluminum alloys and silver alloys. Specific examples of aluminum alloys include AlNd and AlCu.

The metal oxide layer contains, for example, at least one of a mixture of indium oxide and tin oxide (ITO), a mixture of indium oxide and zinc oxide (IZO), and titanium oxide (TiO).

From the point of view of high reflectivity of a visible light region and excellent hole injection characteristics, it is preferable that a material of the first electrode 13 is one or more types selected from materials such as Al, AlCu, TiN, TiO, MoO, and the like among the materials described above.

### Insulating Layer

In the display device 10, as illustrated in FIG. 1, it is preferable that the insulating layer 12 be disposed on the first face side of the drive substrate 11. The insulating layer 12 is disposed between the first electrodes 13 adjacent to each other and electrically separates each first electrode 13 for every light emitting elements 104AR and 104AG (that is, for every subpixel 101R and 101G). In addition, the insulating layer 12 has a plurality of opening parts 12A, and the first face (a face opposing the second electrode 15) of each first electrode 13 is exposed from the opening part 12A.

In the examples illustrated in FIG. 1 and the like, the insulating layer 12 forms the opening parts 12A on an outer peripheral end edge of the first face of the separated first electrode 13.

The insulating layer 12 is made of, for example, an organic material or an inorganic material. The organic material contains, for example, at least one of polyimide and acrylic resin. The inorganic material contains, for example, at least one of silicon oxide, silicon nitride, silicon oxynitride, and aluminum oxide.

### First Light Emitting Layer)

The first light emitting layer 14 is disposed between the first electrode 13 and the second electrode 15. The first light emitting layer 14 is disposed as a layer common to the subpixels 101 corresponding to the first subpixel and the second subpixel. Light generated from the first light emitting layer 14 includes light of a wavelength region corresponding to a color type of the first subpixel and light of a wavelength region corresponding to a color type of the second subpixel. In accordance with this, a light emission color of the first light emitting layer 14 is composed of light emission colors that can be extracted from light of the color type of the first subpixel and light of the color type of 101G. In the example illustrated in FIG. 1, the first light emitting layer 14 is composed of light emission colors that can be extracted from red light that is the color type of the subpixel 101R and green light that is the color type of 101G and, more specifically, generates light acquired by combining light of the wavelength region of the red color and light of the wavelength region of the green color. The color type (the light emission color) of light generated from the first light emitting layer 14 becomes a color type acquired by combining red light and green light.

Although the first light emitting layer 14 is not particularly limited as long as it has a layer structure generating light of a wavelength region corresponding to a predetermined color type, for example, as illustrated in FIG. 3A, a configuration having a configuration in which a hole injection layer 140, a hole transport layer 141, an organic light emitting layer 142, and an electron transport layer 143 are stacked in this order from the first electrode 13 to the second electrode 15 can be employed. An electron injection layer 144 may be disposed between the electron transport layer 143 and the second electrode 15. The electron injection layer 144 is provided for increasing electron injection efficiency. The configuration of the first light emitting layer 14 is not limited thereto, and layers other than the organic light emitting layer 142 are provided as necessary.

The hole injection layer 140 is a buffer layer for increasing the hole injection efficiency for the organic light emitting layer 142 and inhibiting a leakage. The hole transport layer 141 is provided for increasing hole transport efficiency for the organic light emitting layer 142. The electron transport layer 143 is provided for increasing the electron transport efficiency for the organic light emitting layer 142.

In accordance with an application of an electric field, recombination of electrons and holes occurs, and the organic light emitting layer 142 generates light. The organic light emitting layer 142 is an organic layer that contains an organic light emitting material. A light emission dopant of the organic light emitting layer 142 is not limited to a fluorescent material and a phosphorescent material, and any material may be used. For example, the organic light emitting layer 142 has a laminated structure in which the red light emitting layer 142R and the green light emitting layer 142G are stacked. Here, as illustrated in FIG. 3A, a light emission separating layer 145 is disposed between the red light emitting layer 142R and the green light emitting layer 142G.

In accordance with an application of an electric field, some of holes injected from the first electrode 13 through the hole injection layer 140 and the hole transport layer 141 and some of electrons injected from the second electrode 15 through the electron transport layer 143 are recombined, and the red light emitting layer 142R generates red light.

The light emission separating layer 145 is a layer for adjusting injection of carriers into the organic light emitting layer 142, and, by injecting electrons and holes into each layer configuring the organic light emitting layer 142 through the light emission separating layer 145, light emission balance of each color is adjusted.

In accordance with an application of an electric field, some of holes injected from the first electrode 13 through the hole injection layer 140, the hole transport layer 141, and the light emission separating layer 145 and some of electrons injected from the second electrode 15 through the electron transport layer 143 are recombined, and the green light emitting layer 142G generates green light.

### Second Electrode

In the light emitting element 104A, the second electrode 15 is disposed to face the first electrode 13. The second electrode 15 is disposed as an electrode common to the first subpixel and the second subpixel. In the example illustrated in FIG. 1, the second electrode 15 becomes an electrode (common electrode) common to the subpixels 101R and 101G. In addition, the second electrode 15 is further shared also with the third subpixel. In this example, the second electrode 15 is also shared with the subpixel 101B and becomes a common electrode. The second electrode 15 is a cathode electrode. The second electrode 15 is appropriately a transparent electrode having permeability for light generated in the first light emitting layer 14. The transparent electrode described here includes an electrode formed in a transparent conductive layer and an electrode formed to have a laminated structure including a transparent conductive layer and a semi-transmissive reflective layer.

The second electrode 15 is composed of at least one layer out of a metal layer and a metal oxide layer. More specifically, the second electrode 15 is configured of a single-layer film of a metal layer or a metal oxide layer or a laminated film of a metal layer and a metal oxide layer. In a case in which the second electrode 15 is composed of a laminated film, the metal layer may be disposed on the first light emitting layer 14 side, and the metal oxide layer may be disposed on the first light emitting layer 14 side.

As a material of the transparent conductive layer, a transparent conductive material having excellent light permeability and a low work function is appropriately used. The transparent conductive layer, for example, can be formed using a metal oxide. More specifically, examples of the material of the transparent conductive layer include a mixture of an indium oxide and a tin oxide (ITO) and a material containing at least one type of a mixture of an indium oxide and a zinc oxide (IZO) and a zinc oxide (ZnO).

The semi-transmissive reflective layer, for example, can be formed using a metal layer. More specifically, an example of the material of the semi-transmissive reflective layer includes a material containing at least one type of metal element selected from the group consisting of magnesium (Mg), aluminum (Al), silver (Ag), gold (Au) and copper (Cu). The metal layer may contain the at least one metallic element as a constituent element of an alloy. Specific examples of the alloy include a MgAg alloy, a AgPdCu alloy, and the like.

### Second Light Emitting Layer

The second light emitting layer 16 is disposed between the second electrode 15 and the third electrode 17. Light generated from the first light emitting layer 14 includes a main wavelength of light corresponding to the color type of the third subpixel. The second light emitting layer 16 is a layer that generates light corresponding to the color type of the third subpixel. In other words, the color type of light generated from the second light emitting layer 16 is a color type that is able to extract light of the color type of the third subpixel. In the example illustrated in FIG. 1, the second light emitting layer 16 is a layer that is able to generate blue light that is the color type of the subpixel 101B.

In the example illustrated in FIG. 1, for example, it is preferable that the second light emitting layer 16 have a structure in which a hole injection layer, a hole transport layer, a blue light emitting layer, and an electron transport layer are stacked. An electron injection layer may be provided between the electron transport layer and the second electrode 15. The hole injection layer, the hole transport layer, the electron transport layer, and the electron injection layer may be layers similar to those described in the first light emitting layer 14. In addition, the configuration of the second light emitting layer 16 is not limited thereto, and layers other than the organic light emitting layer are disposed as necessary.

In accordance with an application of an electric field, some of holes injected from the third electrode 17 through the hole injection layer and the hole transport layer and some of electrons injected from the second electrode 15 through the electron transport layer are recombined, and the blue light emitting layer generates blue light.

### Third Electrode

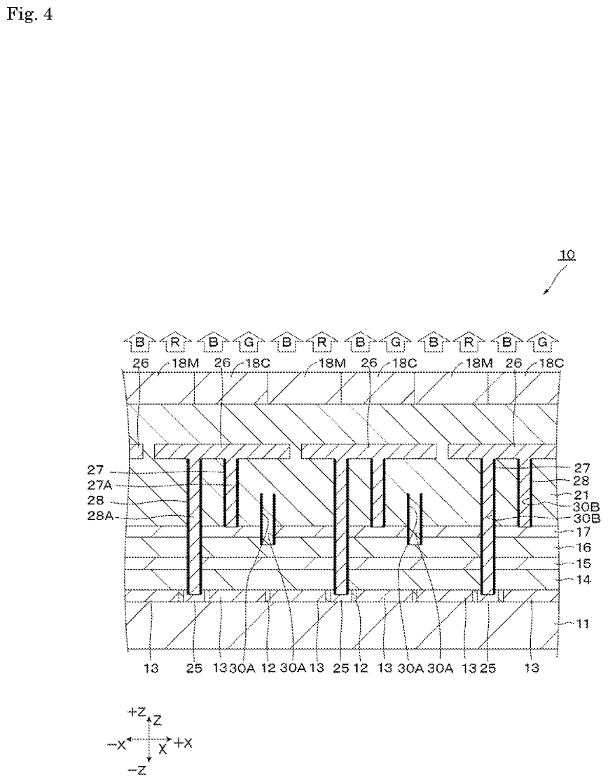

A plurality of third electrodes 17 are disposed on the first face side of the second light emitting layer 16. The third electrodes 17 are electrically separated for each subpixel 101. In the example illustrated in FIG. 1, the third electrode 17 is electrically separated in accordance with the layout of the subpixel 101B as the third subpixel. In addition, the configuration in which the third electrode 17 is separated for each subpixel 101, for example, as illustrated in FIG. 4 and the like, can be realized using an insulating layer 30A to be described below.

Similar to the first electrode 13, the third electrode 17 is an anode electrode. The third electrode 17 uses a transparent electrode having permeability for light generated in the first light emitting layer 14 and the second light emitting layer 16. The transparent electrode described here, as illustrated in the description of the second electrode 15, includes a transparent electrode formed in a transparent conductive layer and a transparent electrode formed to have a laminated structure including a transparent conductive layer and a semi-transmissive reflective layer. As a material of a transparent electrode forming the third electrode 17, a material similar to the material (conductive material) of the transparent electrode that can be used as the first electrode 13 may be used. In addition, as the semi-transmissive reflective layer, a semi-transmissive reflective layer similar to that described in the second electrode 15 may be used.

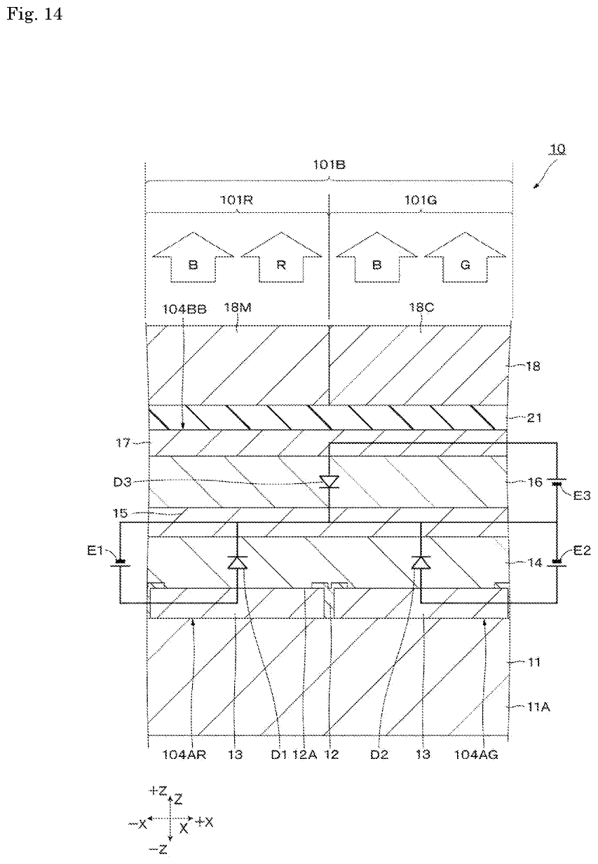

In the display device 10, the first electrode 13 and the third electrode 17 serve as anode electrodes, and the second electrode 15 serves as a cathode electrode (FIG. 1). In addition, in FIG. 1, together with the configuration of the display device 10, a circuit diagram for describing electric control of the light emitting elements 104A and 104B is illustrated as well. As illustrated in FIG. 1, in a case in which power supplies applying electric fields from the drive substrate 11 side to the subpixels 101R, 101G, and 101B are denoted by E1, E2, and E3, regarding directions of electric fields applied to diodes D1, D2, and D3 formed in light emitting elements 104AR, 104AG, and 104BB from the power supplies E1, E2, and E3, the directions of the electric fields applied to the diodes D1 and D2 are opposite to the direction of the electric field applied to the diode D3. The circuit diagram for describing electric control of the light emitting elements 104A and 104B being illustrated as well together with the configuration of the display device 10 is similar also in FIGS. 14, 15, 16, 18, 19, 20, and 22.

### Driving of Subpixel

In the display device 10 according to the first embodiment, individual subpixels (the first subpixel to the third subpixel) are independently driven individually, thereby independently emitting light. This, for example, can be realized by independently performing formation of a conduction state for the first electrode and the third electrode described above. In the example illustrated in FIG. 1, the power supplies E1, E2, and E3 respectively applying electric fields from the drive substrate 11 side to the subpixels 101R, 101G, and 101B are formed, and the subpixels 101R, 101G, and 101B are independently driven. In this case, formation of a conduction state of the third electrode applying an electric field to the subpixel 101B, formation of a conduction state of the first electrode applying an electric field to the subpixel 101R, and formation of a conduction state of the first electrode applying an electric field to the subpixel 101G are independently realized.

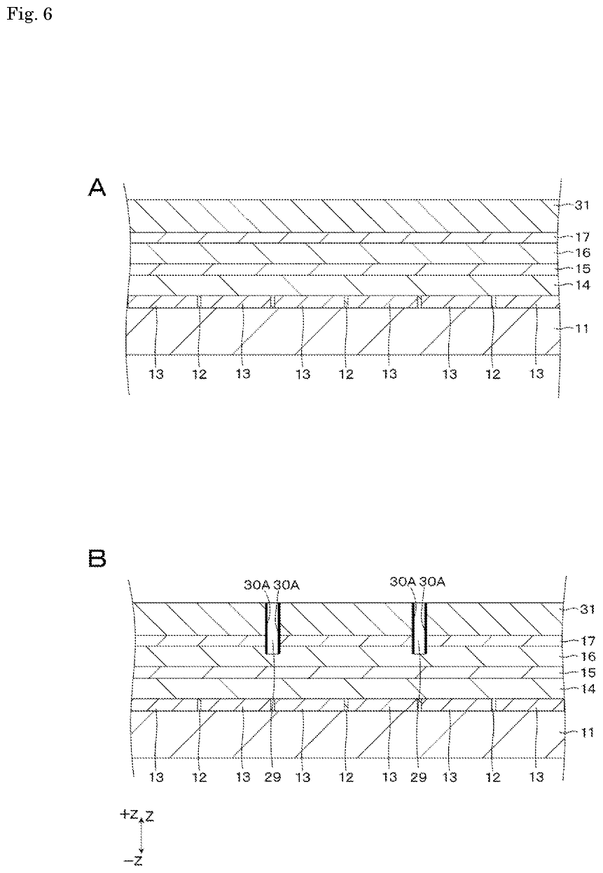

The independent driving of the subpixels 101, for example, as will be described below using FIG. 4 and the like, is realized by individually electrically connecting the first electrode 13 corresponding to the first subpixel and the first electrode 13 and the third electrode 17 corresponding to the second subpixel to a control circuit and the like of the drive substrate 11. FIG. 4 is a cross-sectional view illustrating a wiring structure between the third electrode 17 and circuits of the drive substrate 11 side in the display device 10. The wiring structure has a first relay electrode layer 25, a first contact part 28A, a second relay electrode layer 26, and a second contact part 27A. In the wiring structure, the first relay electrode layer 25 is electrically connected to a circuit through a contact plug at a predetermined position in the drive substrate 11. The first contact part 28A is wiring part having conductivity, is formed in a first contact hole 28, and is connected to the first relay electrode layer 25. The second relay electrode layer 26 is formed on the first face side of the third electrode 17 and electrically connects the first contact part 28A and the second contact part 27A. The second contact part 27A, similar to the first contact part 28A, is a wiring part having conductivity, is formed in the second contact hole 27, and is connected to the third electrode 17. The first relay electrode layer 25 and the second relay electrode layer 26 may be formed using conductive films. In addition, the first relay electrode layer 25, differently from the first electrode 13 and the like, may not have the function as a reflective layer reflecting light. In a case in which a thickness direction (the Z-axis direction) of the first electrode 13 is set as a visual line direction, it is preferable that the first relay electrode layer 25 be smaller than the first electrode 13 as possibly from a point of view of securing the sizes of the subpixels 101R and 101G as large as possible. In this way, as illustrated in the example illustrated in FIG. 4, each third electrode 17 can be connected to the control circuit and the like of the drive substrate 11 through the first relay electrode layer 25, the first contact part 28A, the second relay electrode layer 26, and the second contact part 27A. In addition, each first electrode 13 is connected to the circuit of the drive substrate 11 through a contact plug (not illustrated). In FIG. 4, reference signs 30A and 30B representing a thick line part are insulating layers to be described below. This similarly applies also to FIGS. 6 to 10.

### Protective Layer

On the first face of the third electrode 17, a protective layer 21 is formed. The protective layer 21 blocks the light emitting element 104 from outer air and inhibits penetration of moisture from an external environment to the light emitting element 104. In addition, in a case in which the third electrode 17 has a metal layer, the protective layer 21 may have a function for inhibiting oxidation of this metal layer. Furthermore, in the example illustrated in FIG. 4, in the protective layer 21, a wiring structure connecting the third electrode 17 and the circuit of the drive substrate 11 side is embedded.

The protective layer 21 is formed using an insulating material. As the insulating material, for example, a thermosetting resin or the like may be used. Other than those, as the insulating material, SiO, SiN, SiON, AIO, TiO, or the like may be used. In such a case, as examples of the protective layer 21, there are a CVD film containing SiO, SiON, or the like, an ALD film containing AlO, TiO, SiO, or the like, and the like. The protective layer 21 may be formed in a single layer or may be formed in a state in which a plurality of layers are stacked. In addition, the CVD film represents a film formed using a chemical vapor deposition method. The ALD film represents a film formed using an atomic layer deposition method.

### Color Conversion Layer

In the display device 10 according to the first embodiment, on the first face side of the protective layer 21, color conversion layers are disposed. The color conversion layers are disposed at positions corresponding to the first subpixel and the second subpixel and extract light of color types corresponding to the first subpixel and the second subpixel out of light generated in the first light emitting layer. In addition, for light generated in the second light emitting layer, the color conversion layer extracts light of a color type corresponding to the third subpixel. In the examples illustrated in FIGS. 1 and 4 and the like, the color conversion layer is a color filter 18.

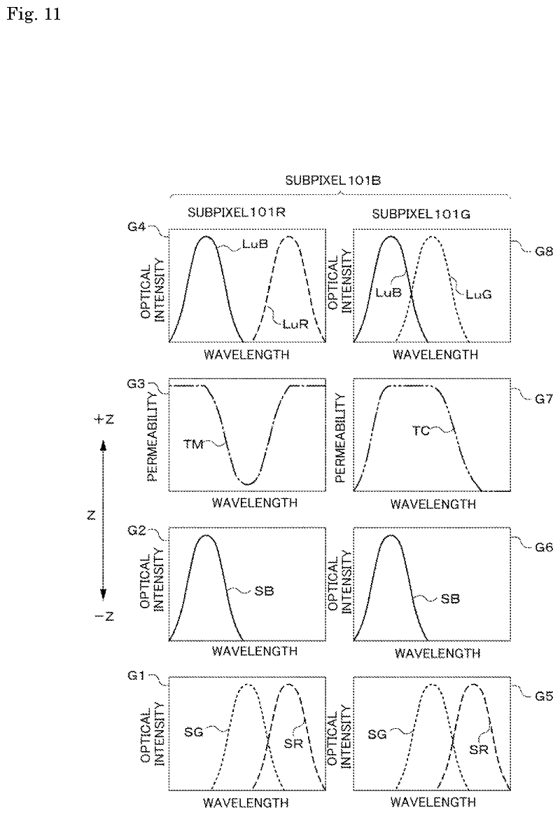

The color filter 18 illustrated in FIG. 1 and the like is disposed on the first face side (the upper side; the +Z direction side) of the protective layer 21. Examples of the color filter 18 include an on-chip color filter (OCCF) and the like. A plurality of color filters 18 are disposed in accordance with the subpixels 101R and 101G. The color filter 18 extracts light of the color types corresponding to the subpixels 101R and 101G out of light generated from the first light emitting layer 14. In addition, the color filter 18 extracts light of the color type corresponding to the subpixel 101B out of light generated from the second light emitting layer 16. As such color filters 18, in the example illustrated in FIG. 1, there are a color filter of a magenta color (a magenta color filter 18M) and a color filter of a cyan color (a cyan color filter 18C). As represented in a graph G3 illustrated in FIG. 11, the magenta color filter 18M is a color filter 18 having a distribution TM of permeabilities for allowing light of a wavelength region of the red color and light of a wavelength region of the blue color out of light of a visible light region to be transmitted (interrupting transmission of light of the wavelength region of the green color). In addition, as represented in a graph G7 illustrated in FIG. 11, the cyan color filter 18C is a color filter 18 having a distribution TC of permeabilities for allowing light of a wavelength region of a blue color and light of a wavelength region of a green color out of light of a visible light region to be transmitted (interrupting transmission of light of a wavelength region of a red color). FIG. 11 is a graph for describing a light extracting mechanism of the display device 10 according to the first embodiment. In FIG. 11, in each layer of the display device 10, from the −Z side, a spectrum distribution diagram (graphs G1 and G5) of light generated from the first light emitting layer 14 configuring the subpixels 101R, 101G, and 101B, a spectrum distribution diagram (graphs G2 and G6) of light generated from the second light emitting layer, a distribution diagram (graphs G3 and G7) of the permeability of the color conversion layer, and a spectrum distribution diagram (graphs G4 and G8) of light extracted from the subpixels 101R, 101G, and 101B are illustrated.

The magenta color filter 18M is formed at a position corresponding to the subpixel 101R in a plan view of the display area 10A (in a case in which the Z-axis direction is set as a visual line direction) and extracts red light to the display area 10A side by passing the red light out of light generated from the first light emitting layer 14 (a graph G4 illustrated in FIG. 11). In addition, the magenta color filter 18M extracts blue light to the display area 10A side by passing the blue light corresponding to the color type of the subpixel 101B out of light generated from the second light emitting layer 16 (the graph G4 illustrated in FIG. 11). The graph G4 illustrated in FIG. 11 is a graph representing a spectrum distribution of light extracted from the position of the subpixel 101R. In the graph, a horizontal axis represents a wavelength, and a vertical axis represents an intensity of extracted light. LuB is a spectrum distribution of light extracted from the second light emitting layer 16 at a position corresponding to the subpixel 101R, and LuR is a spectrum distribution of light extracted from the first light emitting layer 14 at the position corresponding to the subpixel 101R. In addition, the position corresponding to the subpixel 101R becomes a partial area of the subpixel 101B.

The cyan color filter 18C is formed at a position corresponding to the subpixel 101G in the plan view of the display area 10A and extracts green light to the display area 10A side by passing the green light out of light generated from the first light emitting layer 14 (a graph G8 illustrated in FIG. 11). In addition, the cyan color filter 18C extracts blue light to the display area 10A side by passing the blue light corresponding to the color type of the subpixel 101B out of light generated from the second light emitting layer 16 (the graph G8 illustrated in FIG. 11). The graph G8 illustrated in FIG. 11 is a graph representing a spectrum distribution of light extracted from the position of the subpixel 101G. In the graph, a horizontal axis represents a wavelength, and a vertical axis represents an intensity of extracted light. LuB is a spectrum distribution of light extracted from the second light emitting layer 16 at a position corresponding to the subpixel 101G, and LuG is a spectrum distribution of light extracted from the first light emitting layer 14 at the position corresponding to the subpixel 101G. In addition, the position corresponding to the subpixel 101G becomes a partial area of the subpixel 101B.

### Filling Resin Layer

On the first face side of the color conversion layer, a filling resin layer may be formed. In the example illustrated in FIG. 1, on the first face of the color filter 18, a filling resin layer may be formed (not illustrated). The filling resin layer can exhibit a function of smoothing the surface of the first face serving as a formation face of the color conversion layer of the color filter 18 or the like. In addition, the filling resin layer can have a function as a bonding layer bonding a counter substrate to be described below. Examples of the filling resin layer include an ultraviolet curing resin, a thermosetting resin, and the like.

### Counter Substrate

The counter substrate is disposed on the filling resin layer in a state in which it faces the drive substrate 11 (not illustrated). The counter substrate seals the light emitting element 104 together with the filling resin layer. The counter substrate may be formed using the same material as that of the substrate 11A forming the drive substrate 11 and is preferably configured using a material such as glass or the like.

In addition, on the color filter 18, a planarization layer is formed, and, further on the planarization layer, the counter substrate may be disposed through the filling resin layer (not illustrated). The planarization layer may be formed using a material similar to that of the filling resin layer.

### 1-2 Method of Manufacturing Display Device

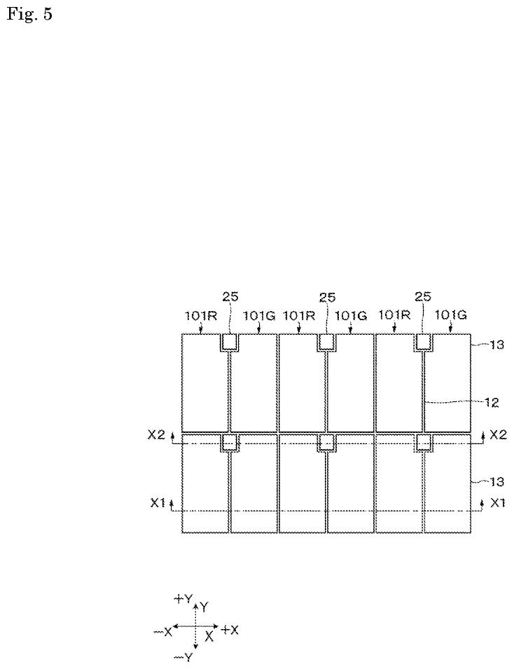

Next, an example of a method of manufacturing the display device 10 will be described in detail using FIGS. 5 to 10. In addition, a case in which the third electrode 17 and the drive substrate 11 are electrically connected through the wiring structure illustrated in FIG. 4 (the first relay electrode layer 25, the first contact part 28A, the second relay electrode layer 26, and the second contact part 27A) will be continued to be described as an example.

By forming circuits such as transistors, various wirings, and the like on a substrate 11A formed from a semiconductor material such as silicon, a drive substrate 11 is formed. A plurality of transistors are disposed in accordance with subpixels 101.

On the drive substrate 11, as illustrated in FIG. 5, for example, by sputtering a material such as an Al alloy or the like in accordance with a pattern of a first electrode 13, the first electrode 13 is patterned. At this time, a first relay electrode layer 25 is patterned together. Next, an insulating layer 12 is formed between first electrodes 13 adjacent to each other or between a first relay electrode layer and the first electrode 13. At this time, an opening part 12A is formed to expose an upper face of the first electrode 13. An insulating layer 12, for example, can be formed by performing patterning using a patterning technology such as lithography, etching, or the like for a front face including an upper side of the first electrode 13. In addition, the first electrode 13 is individually electrically connected to a circuit (for example, a transistor) of the drive substrate 11. Also the first relay electrode layer 25 is individually electrically connected to a circuit (for example, a transistor) of the drive substrate 11 side. FIG. 5 is a plan view illustrating an example of a layout of the first electrodes 13 and the first relay electrode layers 25 formed on the drive substrate 11.

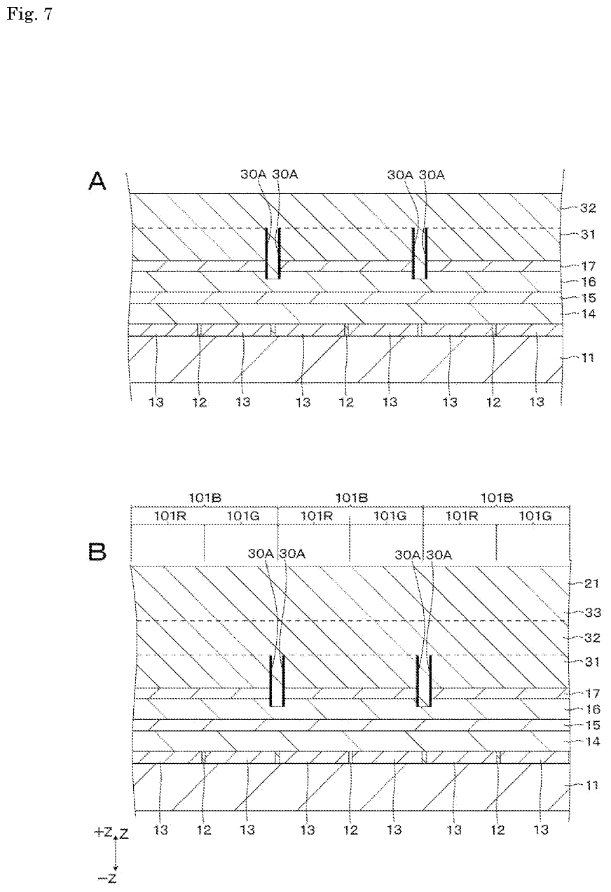

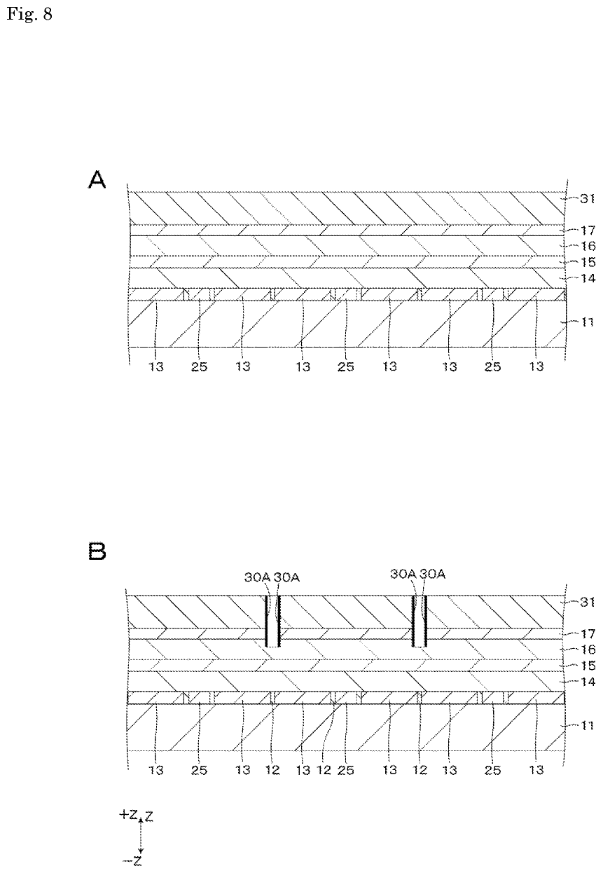

On the first electrode 13, a first light emitting layer 14 is formed on one face. In the formation of the first light emitting layer 14, for example, a deposition method or the like is used. Furthermore, a second electrode 15 (for example, IZO) is formed using a sputtering method or the like. Thereon, a second light emitting layer 16 is formed. Similar to the first light emitting layer 14, the second light emitting layer 16 can be formed using a deposition method or the like. Then, a third electrode 17 is formed. After formation of the third subpixels, a first layer 31 configuring a protective layer 21 is formed. The first layer 31, for example, can be formed by performing a method such as CVD or the like using a material forming the protective layer 21 (FIGS. 6A and 8A). FIG. 6A is a cross-sectional view illustrating a process of manufacturing the display device 10 and is a cross-sectional view schematically illustrating a state of a longitudinal cross-section at the position of line X1-X1 illustrated in FIG. 5. This similarly applies also to FIGS. 6B, 7A, and 7B. FIG. 8A is a cross-sectional view illustrating a process of manufacturing a display device, and FIG. 5 is a cross-sectional view schematically illustrating a state of a longitudinal cross-section of line X2-X2 illustrated in FIG. 5. In addition, this applies also to FIGS. 8B, 9A, 9B, 10A, and 10B.

Next, the first layer 31 is divided for each subpixel 101B in accordance with the layout of the subpixels 101B (the layout of the third subpixels). Similarly, also the third electrode 17 is divided for each subpixel 101B. Such division, for example, as illustrated in FIGS. 6B and 8B, can be realized by forming groove parts 29 between the subpixels 101B adjacent to each other. On a side wall of such a groove part 29, an insulating layer 30A is formed. The insulating layer 30A can be formed by appropriately using a photolithographic technology and a dry etching technology. This insulating layer 30A insulates the third electrodes 17, which are adjacent to each other, from each other. In FIGS. 6B and 8B, the insulating layer 30A is illustrated using a thick line.

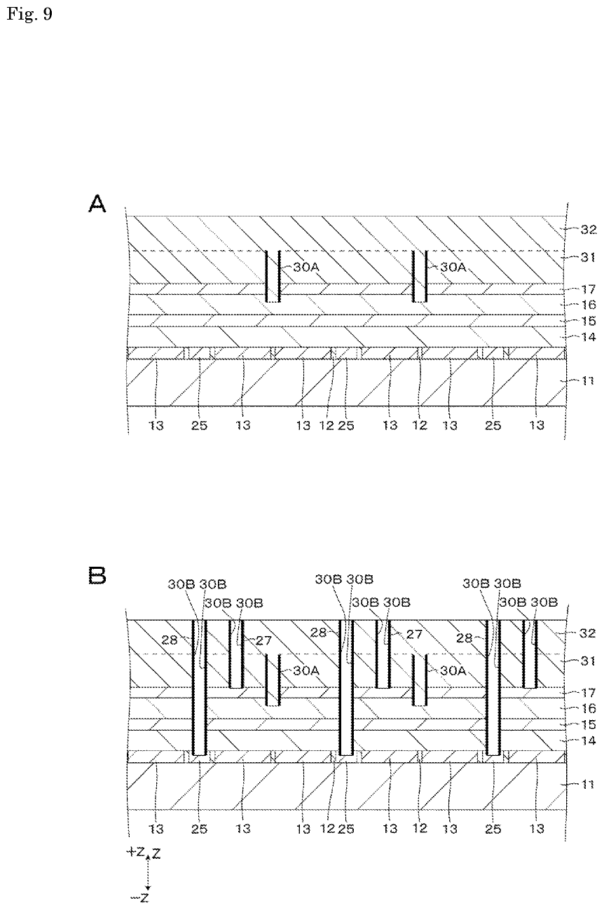

In addition, a second layer 32 is formed such that it fills inner spaces of the groove parts 29 surrounded by the insulating layer 30A and covers the first layer 31 (FIGS. 7A and 9A). The second layer 32 can be formed similar to the first layer 31 and configures the protective layer 21. In addition, in FIGS. 7A and 9A, broken lines represent a boundary between the first layer 31 and the second layer 32. Next, as illustrated in FIG. 9B, a first contact hole 28 extending from the first face side of the second layer 32 to the first relay electrode layer 25 is formed. In addition, a second contact hole 27 extending from the first face side of the second layer 32 to the third electrode 17 is formed. As a method of forming the first contact hole 28 and the second contact hole 27, a method similar to the method of forming the groove parts 29 can be used. In each of inner circumferential wall faces of the first contact hole 28 and the second contact hole 27, an insulating layer 30B is formed. The insulating layer 30B can be formed using a method similar to that of the insulating layer 30A described above. In FIG. 9B, the insulating layer 30B is illustrated using a thick line.

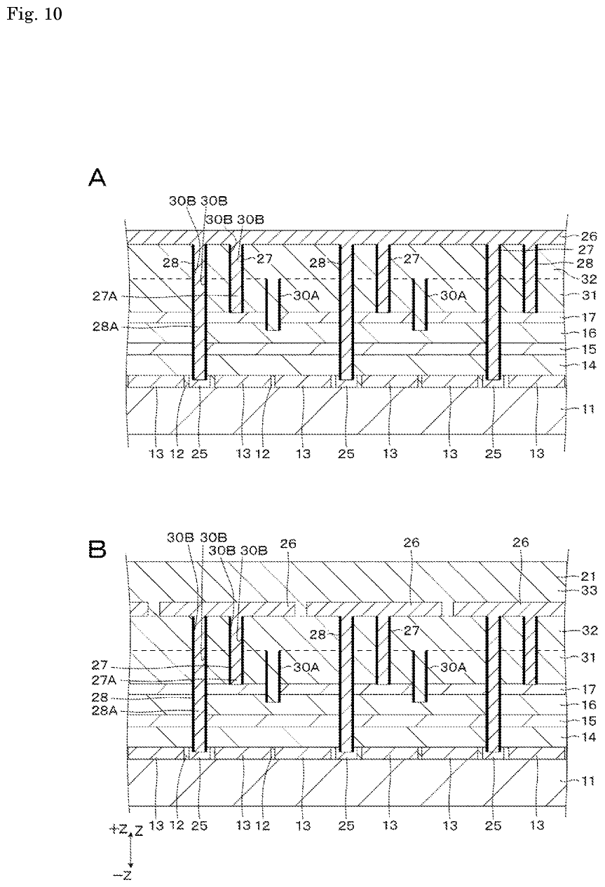

Next, a second relay electrode layer 26 is formed such that it covers the first face of the second layer 32. At this time, a material forming the second relay electrode layer 26 fills the inside of the first contact hole 28 and the second contact hole 27, whereby the first contact part 28A and the second contact part 27A are formed. The first contact part 28A and the second contact part 27A have conductivity. The first relay electrode layer 25 and the second relay electrode layer 26 are electrically connected through the first contact part 28A. In addition, the third electrode 17 and the second relay electrode layer 26 are electrically connected through the second contact part 27A (FIG. 10A).

Then, the second relay electrode layer 26 is divided for each subpixel 101B (FIG. 10B). The division of the second relay electrode layer 26 can be formed by appropriately using a photolithographic technology and a dry etching technology. In addition, a third layer 33 covering the second relay electrode layer 26 is formed (FIGS. 7B and 10B). In FIGS. 7B and 10B, a boundary between the third layer 33 and the second layer 32 and a boundary between the first layer 31 and the second layer 32 are represented using broken lines. The third layer 33 can be formed similar to the first layer 31 and the second layer 32 and configures the protective layer 21. After the protective layer 21 is formed using the first layer 31, the second layer 32, and the third layer 33, color conversion layers such as a color filter 18 and the like are further disposed (FIG. 4). The color conversion layers are appropriately formed using a method according to details thereof. For example, in a case in which the color conversion layer is the color filter 18, the method of forming the color filter 18 is appropriately used. Then, a filling resin layer and a counter substrate are disposed. Thus, the display device 10 is obtained.

### 1-3 Operations and Effects

In the display device 10 according to the first embodiment, anode electrodes are individually disposed in the first subpixel to the third subpixel. In the example illustrated in FIG. 1, the first electrode 13 separated for each of the subpixels 101R and 101G is disposed, and the third electrode 17 is disposed in the subpixel 101B. In addition, individual voltages can be independently applied to the first electrode 13 corresponding to the subpixel 101R and the first electrode 13 corresponding to the subpixel 101G. A voltage can be applied to the third electrode 17 independently from the first electrode 13. In addition, the second electrode is a common electrode common to the subpixels 101R, 101G, and 101B.

When a voltage is applied between the first electrode 13 and the second electrode 15 corresponding to the subpixel 101R, a state in which an electric field is applied to a part of the first light emitting layer 14 that corresponds to the subpixel 101R is formed. At this time, light is generated from the first light emitting layer 14. As illustrated in a graph G1 illustrated in FIG. 11, this light becomes light acquired by combining light having a spectrum distribution SR in the wavelength region of the red color and light having a spectrum distribution SG in the wavelength region of the green color. At this time, in the subpixel 101R, light generated in the first light emitting layer 14 is transferred in the +Z direction in FIG. 11 and passes through the magenta color filter 18M. As illustrated in the distribution TM of permeability of the graph G3, the magenta color filter has high permeability for light of a wavelength region of a red color and low permeability for light of the wavelength region of the green color, and thus light extracted from the first light emitting layer 14 in the subpixel 101R is occupied with light having a spectrum distribution LuR in the wavelength region of the red color as a whole (a graph G4 illustrated in FIG. 11).

When a voltage is applied between the first electrode 13 and the second electrode 15 corresponding to the subpixel 101G, a state in which an electric field is applied to a part of the first light emitting layer 14 that corresponds to the subpixel 101G is formed. At this time, in the subpixel 101G, similar to the description of the subpixel 101R, light acquired by combining light having a spectrum distribution SR in the wavelength region of the red color and light having a spectrum distribution SG in the wavelength region of the green color is generated from the first light emitting layer 14 (a graph G5 illustrated in FIG. 11). At this time, in the subpixel 101G, light generated in the first light emitting layer 14 is transferred in the +Z direction in FIG. 11 and passes through the cyan color filter 18C. As illustrated in the distribution TC of permeability of the graph G7, the cyan color filter has high permeability for light of the wavelength region of the green color and low permeability for light of the wavelength region of the red color, and thus, light extracted from the first light emitting layer 14 in the subpixel 101G is occupied with light having a spectrum distribution LuG in the wavelength region of the green color as a whole (a graph G8 illustrated in FIG. 11).

In addition, when a voltage is applied between the third electrode 17 and the second electrode 15, a state in which an electric field is applied to the second light emitting layer 16 is formed. At this time, light is generated from the second light emitting layer 16. As illustrated in graphs G2 and G6 illustrated in FIG. 11, this light becomes light (blue light) having a spectrum distribution SB in the wavelength region of the blue color. In the subpixel 101B, blue light generated in the second light emitting layer 16 is directed toward the magenta color filter 18M and the cyan color filter 18C. As illustrated in the distributions TM and TC of permeabilities of the graphs G3 and G7, both the magenta color filter 18M and the cyan color filter 18C have permeability for blue light (have high permeability for light of the wavelength region of the blue color), and thus blue light generated in the second light emitting layer 16 passes through both the magenta color filter 18M and the cyan color filter 18C. In this way, the subpixel 101B emits blue light. Thus, light extracted from the second light emitting layer 16 in the subpixel 101B is occupied with light having a spectrum distribution LuB in the wavelength region of the blue color as a whole (graphs G4 and G8 illustrated in FIG. 11).

In this way, by being able to individually apply voltages to the first electrode 13 and the third electrode 17, the subpixels 101R, 101G, and 101B can be caused to individually emit red light, green light, and blue light, and thus the display device 10 can perform full-color display in the display area 10A.

Generally, in a case in which a display device performing full-color display is formed, one pixel is formed using a combination (this may be referred to as a three-color subpixel) of subpixels corresponding to three types of color types including a subpixel corresponding to a red color, a subpixel corresponding to a blue color, and a subpixel corresponding to a green color. In addition, in a case in which three-color subpixels corresponding to three types of color types are disposed using a conventional paint division method, these three types of subpixels are arranged in the state of being aligned in the plane direction of the display area such as being arranged in the same plane as that of the display area or the like. For this reason, in order to form one pixel, it is required to secure an area corresponding to three subpixels. In order to respond to a request for high precision in the display device, it is required to decrease a pitch between pixels adjacent to each other. In a case in which subpixels are formed using a paint division method, each subpixel per pixel becomes small, and thus, light emission luminance of the display device falls.

According to the display device 10 of the first embodiment, in one pixel, the first light emitting layer 14 and the second light emitting layer 16 are stacked through the second electrode 15. The first light emitting layer 14 emits light of a wavelength region corresponding to color types of two types of subpixels (the subpixels 101R and 101G in the example illustrated in FIG. 1). The second light emitting layer 16 emits light of a wavelength region corresponding to a color type of a predetermined subpixel (the subpixel 101B in the example illustrated in FIG. 1). For this reason, under a condition that the pitches between pixels are the same, in a case in which the display device 10 according to the first embodiment is compared with a display device forming three color types of subpixels using the paint division method, the display device 10 side according to the first embodiment can increase the light emission area of subpixels. Thus, according to the display device 10 of the first embodiment, the luminance can be improved more than that of a conventional display device.

In addition, as a display device, a micro display or the like having a small pixel pitch, in order to perform full-color display, may be formed using a type (hereinafter, referred to as a white light emission type) in which color filters according to three types of subpixels and a light emitting layer of a white color common to the three types of subpixels are included. In this type, a color filter performs spectral dispersion by absorbing light of an unnecessary wavelength region and transmitting light of a desired wavelength region. At this time, light absorbed as an unnecessary wavelength region does not contribute to light emission (luminance) of the display device. For example, in a subpixel corresponding to a red color, when light generated from a white light emitting layer passes through the red color filter, blue light and green light are absorbed by a red color filter. For this reason, about ⅔ of light generated from a white light emitting layer is wasted in a subpixel corresponding to the red color (in this specification, light being wasted represents that the light becomes light that is not extracted to the outside of the display device). This similarly applies also to a subpixel corresponding to a blue color and a subpixel corresponding to a green color. For this reason, in the display device, about ⅔ of light generated in the white light emitting layer is not extracted as the whole pixel, and the light emission luminance (light emission efficiency) falls.

In the display device 10 according to the first embodiment, compared to a display device of a white light emission type, waste of light according to passage through a color filter is inhibited. Thus, according to the display device 10 of the first embodiment, the luminance can be improved more than that of a conventional display device 10. For example, in the display device 10 according to the first embodiment, light absorbed by the color filter of the magenta color (the magenta color filter 18M) is green light, and waste of red light and blue light is inhibited (is used for display in the display area 10A). Light absorbed by the color filter of the cyan color (the cyan color filter 18C) is red light, and waste of green light and blue light is inhibited. Thus, although light absorbed by each color filter is two types of color types in a display device of the white light emission type, the light is suppressed to one type of color type in the display device 10 according to the first embodiment.

In a case in which a white light emitting layer common to three types of subpixels is included in a display device, as the white light emitting layer, a structure in which a red light emitting layer, a green light emitting layer, and a blue light emitting layer (a red organic light emitting layer, a green organic light emitting layer, and a blue organic light emitting layer) are stacked is known. In this structure, in order to realize white color light emission, it is important to emit light of a red color, light of a green color, and light of a blue color with a balance. In order to take a balance of light emission of red, green, and blue light emitting layers, a layer adjusting a balance of carriers such as electrons and holes between respective organic light emitting layers is frequently used. In such a case, a drive voltage becomes higher than that of a case in which red, green, and blue light emitting layers are individually caused to emit light.

In the display device 10 according to the first embodiment, the first light emitting layer 14 serving as a light emitting layer of the first subpixel and the second subpixel and the second light emitting layer 16 serving as a light emitting layer of the third subpixel can be independently driven. For this reason, a degree of freedom in design in the display device 10 is improved, optimization of the light emission state of the subpixels 101 can be easily performed, and implementation of a low voltage of the drive voltage can be easily achieved. In the first light emitting layer 14 and the second light emitting layer 16, as described above, light emitting layers such as a blue organic light emitting layer, a red organic light emitting layer, a green organic light emitting layer, and the like are appropriately disposed. In the subpixel 101B, a blue organic light emitting layer is disposed. Generally, a light emission life of a material forming the blue organic light emitting layer is shorter than that of a material forming the red organic light emitting layer or the green organic light emitting layer. Thus, a technology for improving a life of the display device by improving durability of the subpixel 101B has been requested. In the example of the display device 10 according to the first embodiment illustrated in FIG. 1, in the plan view of the display area 10A, the third subpixel (the subpixel 101B illustrated in FIG. 1) is larger than the first subpixel and the second subpixel described above (the subpixels 101R and 101G illustrated in FIG. 1). In this case, even when a voltage applied to the subpixel 101B is suppressed, sufficient luminance of a blue color can be acquired, and the durability of the subpixel 101B can be improved.

### 1-4 Modified Example

Next, modified examples of the display device 10 according to the first embodiment will be described.

### Modified Example 1

In the display device 10 according to the first embodiment, as an example of a case in which the first light emitting layer 14 is configured to emit light with a light emission color capable of extracting red light and green light, a case in which a red organic light emitting layer (the red light emitting layer 142R) and a green organic light emitting layer (the green light emitting layer 142G) are disposed in the first light emitting layer 14 has been described, but a configuration capable of extracting red light and green light from the first light emitting layer 14 is not limited thereto.

In the display device 10 according to the first embodiment, in a case in which the first light emitting layer 14 is configured to emit light with a light emission color capable of extracting red light and green light, the configuration of the first light emitting layer 14 is not limited to that described above and, for example, may have a configuration as illustrated in FIG. 3B (Modified Example 1). The example illustrated in FIG. 3B is a diagram illustrating an example of a first light emitting layer 14 of a display device 10 according to Modified Example 1. In the example illustrated in FIG. 3B, the first light emitting layer 14 has a structure in which a hole injection layer 140, a hole transport layer 141, a yellow light emitting layer 142Y, and an electron transport layer 143 are stacked. This structure is a structure having the yellow light emitting layer 142Y as the organic light emitting layer 142. Similar to the case of FIG. 3A, also in the case of FIG. 3B, an electron injection layer 144 may be disposed between the electron transport layer 143 and the second electrode 15.

In accordance with an application of an electric field, holes injected from the first electrode 13 through the hole injection layer 140 and the hole transport layer 141 and electrons injected from the second electrode 15 through the electron transport layer 143 are recombined, and the yellow light emitting layer 142Y is a layer that generates yellow light. As this layer, an organic light emitting layer is appropriately used. Yellow light is light having a spectrum distribution in both wavelength regions including a wavelength region of a red color and a wavelength region of a green color. For this reason, as in Modified Example 1, in accordance with the first light emitting layer 14 emitting yellow light, light of the wavelength region of the red color and light of the wavelength region of the green color can be extracted using the color conversion layer.

### Modified Example 2

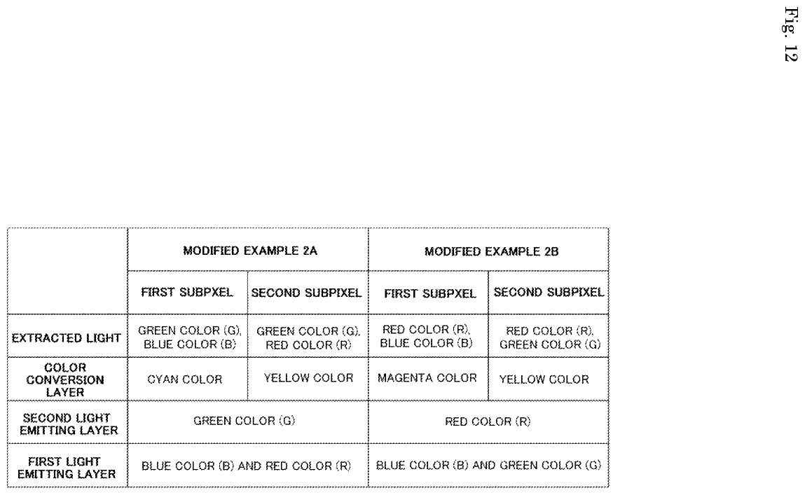

In the display device 10 according to the first embodiment, a combination of color types of light emission colors of the first light emitting layer 14 and the second light emitting layer 16 and a color type of the light conversion layer (the color type of the color filter 18) is not limited to the combination illustrated in FIG. 1 and may be each combination of color types as illustrated in FIG. 12. FIG. 12 is a table illustrating combination of a color type of light generated in the organic light emitting layer 142 of the first light emitting layer 14, a color type of light generated in the organic light emitting layer 142 of the second light emitting layer 16, and a color type of the color conversion layer of a part corresponding to each of the first subpixel and the second subpixel (a color type of a case in which the permeability is replaced with an optical intensity in the distribution spectrum of permeability) in the display device 10 according to Modified Example 2.

In the display device 10 according to Modified Example 2, Modified Example 2A illustrated in FIG. 12 is an example of a combination of color types of the first light emitting layer 14, the second light emitting layer 16, and the light conversion layer (the color filter 18 and the like) of a case in which the first subpixel is the blue subpixel 101B, the second subpixel is the red subpixel 101R, and the third subpixel is the green subpixel 101G. In this case, the first light emitting layer 14 becomes a combination of the blue organic light emitting layer and the red organic light emitting layer (in other words, the light emission color of the first light emitting layer 14 is a color acquired by combining color types of the blue color and the red color), and the second light emitting layer 16 becomes a green organic light emitting layer (in other words, the light emission color of the second light emitting layer is a green color). In addition, the color conversion layer becomes a layer capable of extracting a blue color and a green color in a part corresponding to the first subpixel and becomes a layer capable of extracting a red color and a green color in a part corresponding to the second subpixel. For example, the color conversion layer is a cyan color filter (a color type of the color conversion layer is a cyan color) in a part corresponding to the first subpixel and is a yellow color filter (a color type of the color conversion layer is a yellow color) in a part corresponding to the second subpixel. In accordance with this, in a part corresponding to the first subpixel (the subpixel 101B in Modified Example 2A), blue light is extracted in accordance with light generated in the first light emitting layer 14 passing through a cyan color filter, and green light is extracted in accordance with light generated in the second light emitting layer 16 passing through a cyan color filter (color types of extracted light are a green color and a blue color). In a part corresponding to the second subpixel, red light is extracted in accordance with light generated in the first light emitting layer 14 passing through a yellow color filter, and green light is extracted in accordance with light generated in the second light emitting layer 16 passing through a yellow color filter (color types of extracted light are a green color and a red color).

In the display device 10 according to Modified Example 2, Modified Example 2B illustrated in FIG. 12 is an example of a combination of color types of the first light emitting layer 14, the second light emitting layer 16, and the light conversion layer (the color filter 18 and the like) of a case in which the first subpixel is the blue subpixel 101B, the second subpixel is the green subpixel 101G, and the third subpixel is the red subpixel 101R. In this case, the first light emitting layer 14 becomes a combination of the blue organic light emitting layer and the green organic light emitting layer (in other words, the emission color of the first light emitting layer 14 is a color acquired by combining color types of the blue color and the green color), and the second light emitting layer 16 becomes a red organic light emitting layer (in other words, the light emission color of the second light emitting layer is a red color). In addition, the color conversion layer becomes a layer capable of extracting a blue color and a red color in a part corresponding to the first subpixel and becomes a layer capable of extracting a red color and a green color in a part corresponding to the second subpixel. For example, the color conversion layer is a magenta color filter (a color type of the color conversion layer is a magenta color) in a part corresponding to the first subpixel and is a yellow color filter in a part corresponding to the second subpixel.

In accordance with this, in a part corresponding to the first subpixel, blue light is extracted in accordance with light generated in the first light emitting layer 14 passing through a magenta color filter, and red light is extracted in accordance with light generated in the second light emitting layer 16 passing through a magenta color filter (color types of extracted light are a blue color and a red color). In a part corresponding to the second subpixel, green light is extracted in accordance with light generated in the first light emitting layer 14 passing through a yellow color filter, and red light is extracted in accordance with light generated in the second light emitting layer 16 passing through a yellow color filter (color types of extracted light are a red color and a green color).

### Modified Example 3

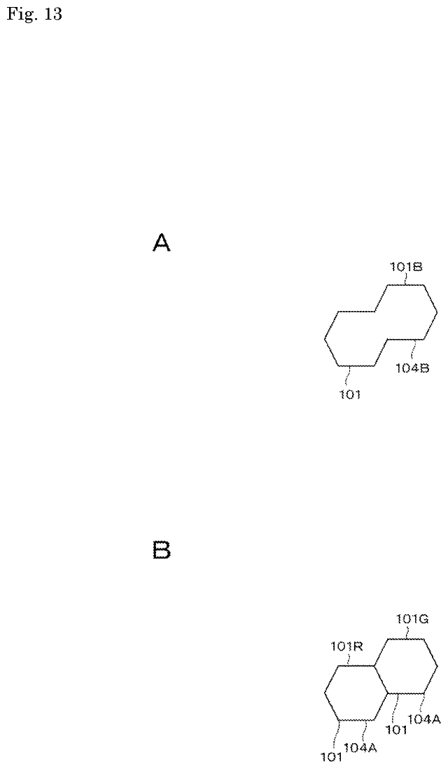

In the display device 10 according to the first embodiment, the layout of subpixels is not limited to the examples illustrated in FIGS. 2B and 2C. The subpixels, for example, may have layouts as illustrated in FIGS. 13A and 13B (Modified Example 3). FIGS. 13A and 13B are plan views illustrating examples of the layout of subpixels in a display device of Modified Example 3. In the example of Modified Example 3 illustrated in FIG. 13B, a layout in which a subpixel 101R that is an example of the first subpixel and a subpixel 101G that is an example of the second subpixel are set in a polygonal shape such as a delta shape or the like is formed, and a combination of the subpixel 101R and the subpixel 101G is aligned in a predetermined direction. In addition, also at this time, as illustrated in FIG. 13A, a layout in which the subpixel 101B that is an example of the third subpixel is defined in a shape covering the subpixels 101R and 101G (set in a shape acquired by combining two polygons) may be formed.

### Modified Example 4

In the display device 10 according to the first embodiment, the opening part 12A of the insulating layer 12 is not limited to a case in which it is positioned on an outer circumferential end edge of the first face of the separated first electrode 13. The opening part 12A of the insulating layer 12, for example, may be formed as illustrated in FIG. 14 (Modified Example 4). FIG. 14 is a plan view illustrating an example of the display device of Modified Example 4.

As illustrated in the example illustrated in FIG. 14, in the display device 10, the insulating layer 12 may cover an area extending from a peripheral edge part of the first face of the separated first electrode 13 over the side face (end face). In this case, each opening part 12A is arranged on the first face of each first electrode 13. At this time, the first electrode 13 is exposed from the opening part 12A, and this exposed area defines a light emission area of the light emitting element 104A. In this specification, the peripheral edge part of the first face of the first electrode 13 represents an area having a predetermined width from the outer circumferential end edge of the first face side of each first electrode 13 to the inner side of the first face.

### 2 Second Embodiment

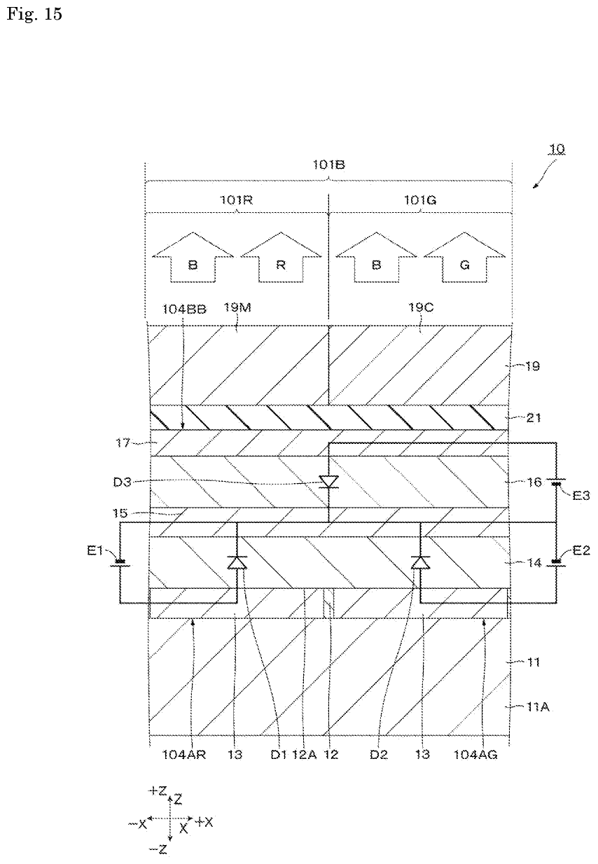

The display device 10 illustrated in the first embodiment described above, as illustrated in FIG. 15, is not limited to a case in which the color conversion layer is the color filter 18. In the display device 10 illustrated in the first embodiment, the color conversion layer may be a multi-layer interference layer 19 (second embodiment). FIG. 15 is a cross-sectional view illustrating an example of a display device 10 according to the second embodiment.

### Multi-Layer Interference Layer

An example of the multi-layer interference layer 19 includes a layer having a dielectric laminated structure (for example, a dielectric laminated film or the like). The multi-layer interference layer 19 has a function of transmitting light of a specific wavelength region and reflecting light of a remaining wavelength region using interference of light according to a thin film. More specifically, an example of the multi-layer interference layer 19 includes a dichroic mirror. In the display device 10 according to the second embodiment, in a case in which a direction along the thickness of the light emitting element 104 as a color conversion layer (a Z-axis direction in FIG. 15) is set as a visual line direction, a first multi-layer interference layer is disposed in a part corresponding to a first subpixel (a part corresponding to a subpixel 101R), and a second multi-layer interference layer is disposed in a part corresponding to a second subpixel (a part corresponding to a subpixel 101G). The first multi-layer interference layer transmits light of a wavelength region corresponding to a color type of the first subpixel and light of a wavelength region corresponding to a color type of a third subpixel (a subpixel 101B). The second multi-layer interference layer transmits light of a wavelength region corresponding to a color type of the second subpixel and light of a wavelength region corresponding to a color type of the third subpixel. In the example illustrated in FIG. 15, the first multi-layer interference layer is a multi-layer interference layer 19M, and the second multi-layer interference layer is a multi-layer interference layer 19C. The multi-layer interference layer 19M transmits light of a wavelength region of a red color corresponding to the subpixel 101R and light of a wavelength region of a blue color corresponding to the subpixel 101B. The multi-layer interference layer 19C transmits light of a wavelength region of a green color corresponding to the subpixel 101G and light of a wavelength region of a blue color corresponding to the subpixel 101B.

According to the display device 10 of the second embodiment, effects similar to those of the display device according to the first embodiment can be acquired.

### 3. Third Embodiment

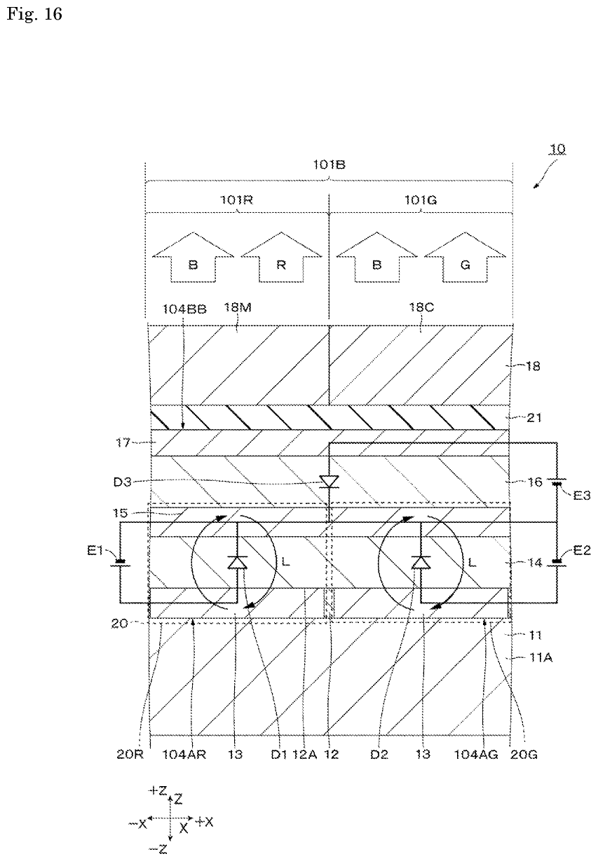

The display device 10 according to the first embodiment or the second embodiment, as illustrated in FIG. 16, may have a resonator structure (third embodiment). FIG. 16 is a cross-sectional view illustrating an example of a display device 10 according to the third embodiment.

### 3-1. Configuration of Display Device

The display device 10 according to the third embodiment illustrated in the example of FIG. 16 may have a configuration similar to that of the display device according to the first embodiment or the second embodiment except for inclusion of a resonator structure.

### Resonator Structure

In the display device 10 according to the third embodiment, a resonator structure 20 is formed. In the display device 10, the resonator structure 20 is formed in a light emitting element 104. The resonator structure 20 illustrated in the example of FIG. 16 is a cavity structure. In the example illustrated in FIG. 16, the resonator structure 20 includes a first electrode 13, a first light emitting layer 14, and a second electrode 15. The cavity structure illustrated in this example is a structure in which light generated from the first light emitting layer 14 is caused to resonate. The light generated from the first light emitting layer 14 being caused to resonate represents that light of a specific wavelength out of light L generated from the first light emitting layer 14 being caused to resonate.

In the example of the display device 10 illustrated in FIG. 16, light (generated light) generated in the first light emitting layer 14 is light acquired by causing light of a wavelength region of the red color and light of a wavelength region of the green color to face each other. The resonator structure 20 causes light of a specific wavelength included in the generated light to resonate. At this time, the light of the predetermined wavelength out of the generated light is intensified. Then, the light is discharged from the second electrode 15 side (that is, the light emitting face side) of the light emitting element 104 to the outside in a state in which the light of the predetermined wavelength is intensified. In addition, the light of the predetermined wavelength is light corresponding to a color type set in advance and represents light corresponding to a color type determined in accordance with the subpixel 101. In the example illustrated in FIG. 16, in the display device 10, resonator structures 20R and 20G are formed in correspondence with light emitting elements 104AR and 104AG corresponding to the subpixels 101R and 101G. In the resonator structure 20R, red light out of light generated from the first light emitting layer 14 is caused to resonate. From the second electrode 15 of the light emitting element 104AR, light in which red light is intensified is discharge to the outside. In the resonator structure 20G, green light out of light generated from the first light emitting layer 14 is caused to resonate by a mechanism similar to the resonator structure 20R. In the subpixel 101G, light in which green light is intensified is discharged from the second electrode 15. In this specification, in a case in which the resonator structures 20R and 20G do not need to be distinguished from each other, it will be referred to as a resonator structure 20.

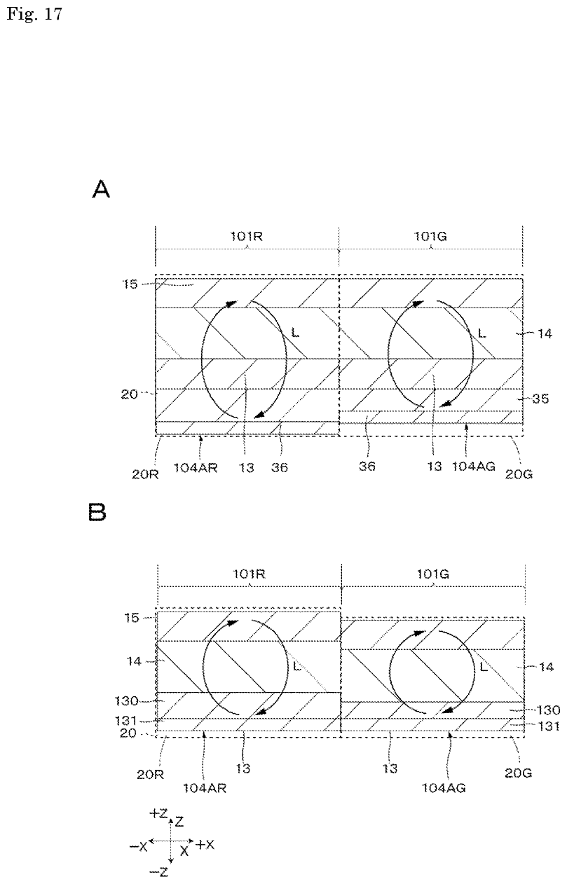

An example of the resonator structure 20 (20R and 20G), for example, includes a configuration as illustrated in FIG. 17A. FIG. 17A is a diagram schematically illustrating a main part of the configuration of the resonator structure of a case in which the resonator structure 20 causes light generated from the first light emitting layer 14 to resonate. In the example of FIG. 17A, a reflective plate 36 is separately arranged on the second face side of the first electrode 13, resonance of light generated from the first light emitting layer 14, for example, is formed in accordance with light reflection between the second electrode 15 and the reflective plate 36. In the case of this example, the resonator structure 20 includes such a reflective plate 36, an optical path adjusting layer 35, a first electrode 13, a first light emitting layer 14, and a second electrode 15. In addition, in this example, the second electrode 15 is formed using a semi-transmissive reflective layer, and the first electrode 13 is formed using a transparent electrode layer. The reflective plate 36 is disposed at a predetermined position on the second face side of the first electrode 13, and the optical path adjusting layer 35 is formed between the reflective plate and the first electrode 13. A position of the reflective plate 36 (a depth (thickness) of the optical path adjusting layer 35 with reference to the position of the first electrode 13) becomes a position for realizing an optical path length set in accordance with a color type of the subpixel 101. The optical path length described here represents an optical path length (it may be referred to as an optical distance) between the second electrode 15 and the reflective plate 36. The optical path adjusting layer 35, for example, may be formed using a material having an insulating property.

The optical path length is set in accordance with light of a color type set in advance. The color type set in advance is a color type with which light is desired to be emitted by the subpixel 101. For example, in the resonator structure 20R formed in the subpixel 101R, an optical path length between the second electrode 15 and the reflective plate 36 is set such that red light out of generated light is caused to resonate. In the resonator structure 20G formed in the subpixel 101G, an optical path length between the second electrode 15 and the reflective plate 36 is set such that green light out of generated light is caused to resonate.

In addition, the resonator structure 20 illustrated in FIG. 17A is an example and is not particularly limited to the example illustrated in FIG. 17A as long as it is a structure capable of forming a cavity structure. For example, as illustrated in FIG. 17B, by adjusting the thickness of the transparent electrode layer 130 of the first electrode 13 using a lamination of a transparent electrode layer 130 as the first electrode 13 and a reflective layer 131 having light reflectivity, the resonator structures 20R and 20G may be formed. In addition, the reflective layer 131 may be formed similar to the reflective plate 36.

### 3-2 Operations and Effects

In the display device 10 according to the third embodiment, effects similar to those of the display device according to the first embodiment can be acquired. In addition, in the display device 10 according to the third embodiment, by disposing the resonator structure 20, color purity can be improved.

### 3-3 Modified Example

### Modified Example 1

In the example illustrated in FIG. 16, although a case in which the resonator structure 20 is formed in each of the light emitting elements 104AR and 104AG having the first light emitting layer has been described, the display device 10 according to the third embodiment is not limited thereto. In the display device 10 according to the third embodiment, the resonator structure 20 may be disposed in the subpixel 101B (not illustrated).

### Modified Example 2

In the example illustrated in FIG. 16, although a case in which the color conversion layer is disposed in the display device 10 using the color filter 18 as an example has been described, the display device 10 according to the third embodiment is not limited thereto. In the display device 10 according to the third embodiment, in a case in which the resonator structure 20 is formed, the color conversion layer may be omitted (not illustrated).

### 4. Fourth Embodiment

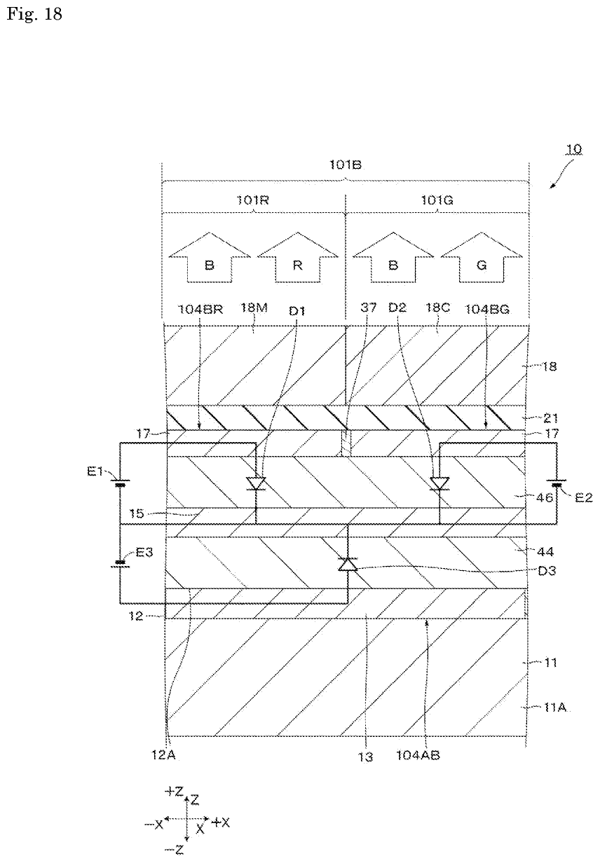

In the display devices 10 according to the first embodiment to the third embodiment described above, although the light emitting element 104 forming the third subpixel is formed on the display face side (the first face side; +Z direction side) of the light emitting elements 104 forming the first subpixel and the second subpixel, the arrangement of the light emitting element 104 forming each subpixel 101 is not limited thereto. In other words, in the display devices 10 according to the first embodiment to the third embodiment described above, as illustrated in FIG. 18, the light emitting element 104 side forming the first subpixel and the second subpixel (in FIG. 18, the subpixels 101R and 101G) may be formed on the display face side (the first face side; the +Z direction side) of the light emitting element 104 forming the third subpixel (in FIG. 18, the subpixel 101B). In FIG. 18, among the light emitting elements 104B, all the parts corresponding to the subpixels 101R and 101G are described as light emitting elements 104BR and 104BG. In the example illustrated in FIG. 18, in order to disclose that the light emitting element 104A becomes a light emitting element corresponding to the subpixel 101B, it will be referred to as a light emitting element 104AB.

In a display device 10 according to a fourth embodiment, a first electrode 13 is formed in a layout corresponding to a third subpixel. Thus, in the example illustrated in FIG. 18, the first electrode 13 is arranged in accordance with a layout of the subpixel 101B.

A first light emitting layer 44 emits light with a color type corresponding to the third subpixel. Thus, the first light emitting layer 44 generates light of a wavelength region of a blue color corresponding to a color type of the subpixel 101B. In other words, the first light emitting layer 44 corresponds to the second light emitting layer 16 illustrated in the display devices 10 according to the first embodiment to the third embodiment. Similar to the first embodiment, the second electrode 15 serves as a common electrode common to a first subpixel to a third subpixel (subpixels 101R, 101G, and 101B).

The second light emitting layer 46 generates light acquired by combining light of a wavelength region corresponding to a color type of the first subpixel (the subpixel 101R) and light of a wavelength region corresponding to a color type of the second subpixel (the subpixel 101G). Thus, the first light emitting layer 44 generates light acquired by combining light of the wavelength region of the red color and light of the wavelength region of the green color corresponding to the color types of the subpixels 101R and 101G. In other words, the second light emitting layer 46 corresponds to the first light emitting layer 14 represented in each of the display devices 10 according to the first embodiment to the third embodiment described above.

The third electrode 17 is formed in a layout corresponding to the first subpixel and the second subpixel. Thus, in the example illustrated in FIG. 18, the third electrode 17 is arranged in correspondence with the layout of the subpixels 101R and 101G. As illustrated in the first embodiment, the separation of the subpixels 101R and 101G can be separated using a configuration similar to the insulating layer 30A separating individual subpixels 101B. In the example illustrated in FIG. 18, an insulating layer 37 is formed between the third electrode 17 corresponding to the subpixel 101R and the third electrode 17 corresponding to the subpixel 101G. In the other points, the display device according to the fourth embodiment may be formed similar to each of the display devices according to the first embodiment to the third embodiment.

According to the display device 10 of the fourth embodiment, effects similar to those of the display device according to the first embodiment can be acquired.

### 5. Fifth embodiment

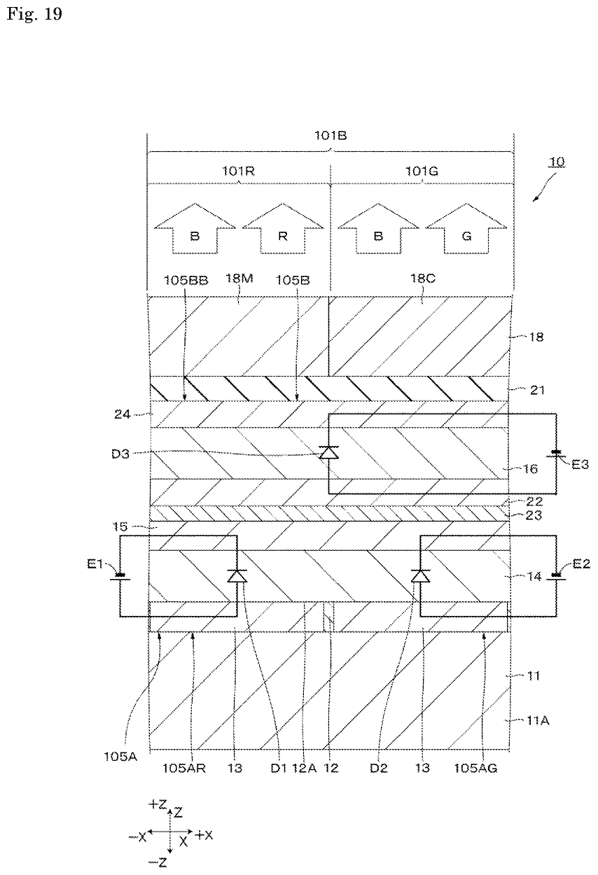

In each of the display devices 10 according to the first embodiment to the fourth embodiment described above, among the first subpixel to the third subpixel (the subpixels 101R, 101G, and 101B), although each of the first subpixel and the second subpixel has the second electrode 15, and the third subpixel shares the second electrode 15, the configuration of the subpixels 101 is not limited thereto. In each of the display devices 10 according to the first embodiment to the fourth embodiment, as illustrated in FIG. 19, each of the first subpixel and the second subpixel (the subpixels 101R and 101G) may have a first electrode 13 and a second electrode 15, and the third subpixel (the subpixel 101B) may have a third electrode 22 and a fourth electrode 24 (a fifth embodiment). FIG. 19 is a diagram illustrating an example of a display device 10 according to a fifth embodiment.

### 5-1. Configuration of Display Device

The display device 10 according to the fifth embodiment, as illustrated in FIG. 19, includes a drive substrate 11 and a plurality of light emitting elements 105A and 105B. In addition, the display device 10 according to the fifth embodiment includes a subpixel 101R as a first subpixel, a subpixel 101G as a second subpixel, and a third subpixel as a subpixel 101B.

A light emitting element 105A is formed in the subpixels 101R and 101G. In the light emitting element 105A, a part corresponding to the subpixel 101R will be referred to as a light emitting element 105AR. In the light emitting element 105A, a part corresponding to the subpixel 101G will be referred to as a light emitting element 105AG. In addition, a light emitting element 105B is formed in the subpixel 101B. In a case in which the light emitting element 104B corresponding to the subpixel 101B is to be specified, it will be referred to as a light emitting element 105BB. In addition, in a case in which the light emitting elements 105AR, 105AG, and 105BB do not need to be distinguished from each other, the light emitting elements 105AR, 105AG, and 105BB will be collectively referred to as a light emitting element 105.

Similar to the light emitting element 104A according to the first embodiment, the light emitting element 105A includes a first electrode 13, a first light emitting layer 14, and a second electrode 15, The first electrode 13 and the second electrode 15 form one pair of electrodes applying an electric field to the first light emitting layer 14.

In the display device 10 according to the fifth embodiment, the subpixels 101R and 101G are configured similar to those of the first embodiment. Thus, the subpixels 101R and 101G includes the first electrode 13, the first light emitting layer 14, and the second electrode 15, and the first electrode 13 and the second electrode 15 are stacked with the first light emitting layer 14 interposed therebetween.

The light emitting element 105B (the light emitting element 105BB) includes a third electrode 22, a second light emitting layer 16, and a fourth electrode 24. In the example illustrated in FIG. 19, the third electrode 22, the second light emitting layer 16, and the fourth electrode 24 are sequentially stacked in a direction from the second face to the first face. The third electrode 22 and the fourth electrode 24 form one pair of electrodes applying an electric field to the second light emitting layer 16. Thus, the subpixels 101R and 101G include the third electrode 22, the second light emitting layer 16, and the fourth electrode 24.

### Insulating Layer

In the display device 10 according to the fifth embodiment, on the first face side of the second electrode 15, the third electrode 22 is formed. At this time, an insulating layer 23 is disposed between the second electrode 15 and the third electrode 22. The second electrode 15 and the third electrode 22 are stacked through the insulating layer 23, whereby the second electrode 15 and the third electrode 22 are separated from each other. The insulating layer 23 may be formed using a material similar to the material of the insulating layer 12.

### Third Electrode

Similar to the third electrode 17 according to the first embodiment, the third electrode 22 serves as an anode electrode of the third subpixel (in the example illustrated in FIG. 19, the subpixel 101B). As a material and a configuration of the third electrode 22, the material and the configuration that can be used in the third electrode 17 according to the first embodiment can be used. In addition, similar to the first embodiment, the layout of the third electrode 22 is a layout corresponding to the arrangement of the third subpixel (the subpixel 101B). A plurality of third electrodes 22 separated in correspondence with the third subpixel (the subpixel 101B) are formed.

### Second Light Emitting Layer

In the display device 10 according to the fifth embodiment, on the first face side of the third electrode 22, the second light emitting layer 16 is formed. The second light emitting layer 16 is similar to the second light emitting layer 16 according to the first embodiment. In the example of FIG. 19, the second light emitting layer 16 is a layer that emits light of a blue color.

### Fourth Electrode

On the first face side of the second light emitting layer 16, a fourth electrode 24 is disposed. Thus, a state in which the third electrode 22 and the fourth electrode 24 are stacked with the second light emitting layer 16 interposed therebetween is formed. The display device 10 according to such a fifth embodiment, on the drive substrate 11, includes a plurality of first electrodes 13, a first light emitting layer 14, a second electrode 15, an insulating layer 23, a plurality of third electrodes 22, a second light emitting layer 16, and a fourth electrode 24 in order. In other words, in the display device 10 according to the fifth embodiment, between the first light emitting layer 14 and the second light emitting layer 16, the second electrode 15 and the third electrode 22 are arranged, and the insulating layer 23 separating the second electrode 15 and the third electrode 22 from each other is disposed.

The fourth electrode 24 is disposed to face the third electrode 17. The third electrode 17 and the fourth electrode 24 form one pair of electrodes, and this one pair of electrodes is arranged to have the second light emitting layer 16 interposed therebetween. In the example illustrated in FIG. 19, the fourth electrode 24 is disposed as an electrode common to the subpixel 101B. In addition, the fourth electrode 24 is a cathode electrode. A material and a configuration of the fourth electrode 24 may be similar to the material and the configuration of the second electrode 15 described in the first embodiment.

In the display device according to the fifth embodiment, the first electrode 13 and the third electrode 22 serve as anode electrodes, and the second electrode 15 and the fourth electrode 24 serve as cathode electrodes (FIG. 19). In addition, in FIG. 19, together with the configuration of the display device 10, a circuit diagram for describing electric control of the light emitting elements 105A and 105B is illustrated together. As illustrated in FIG. 19, in a case in which power supplies applying electric fields from the drive substrate 11 side to the subpixels 101R, 101G, and 101B are denoted by E1, E2, and E3, regarding directions of electric fields applied to diodes D1, D2, and D3 formed in the light emitting elements 105AR, 105AG, and 105BB from the power supplies E1, E2, and E3, the directions of electric fields applied to the diodes D1 and D2 are the same as the direction of the electric field applied to the diode D3.

### Color Conversion Layer

Similar to the first embodiment, the display device according to the fifth embodiment has a color conversion layer. In the example illustrated in FIG. 19, as the color conversion layer, similar to the first embodiment, a color filter 18 is used. In addition, as illustrated in the second embodiment and the like, the color conversion layer may have a configuration other than the color filter 18 such as a multi-layer interference layer 19 or the like.

In addition, in the display device according to the fifth embodiment, similar to the first embodiment, it is preferable to dispose a filling resin layer and a counter substrate such that they cover the color conversion layer.

### 5-2 Operations and Effects

In the display device 10 according to the fifth embodiment, similar to the display device according to the first embodiment, the subpixels 101R and 101G and the subpixel 101B are formed to overlap each other, and the subpixels 101R and 101G have the first light emitting layer 14. Thus, in the display device 10 according to the fifth embodiment, effects similar to those of the first embodiment can be acquired.

### 6 Sixth Embodiment

### 6-1 Configuration of Display Device

In each of the display devices 10 according to the first embodiment to the fifth embodiment described above, although the color conversion layer is disposed, the display device according to the present disclosure is not limited thereto. For example, in a case in which the display device is of a type in which two-color display is performed using three types of subpixels, in each of the display devices 10 according to the first embodiment to the fifth embodiment, as illustrated in FIG. 20, the color conversion layer may be omitted (a sixth embodiment). FIG. 20 is a diagram illustrating an example of a display device 10 according to a sixth embodiment. In the example of FIG. 20, a case in which the display device 10 according to the sixth embodiment has a structure acquired by omitting the color conversion layer from the display device 10 according to the first embodiment is illustrated as an example.

In the display device 10 according to the sixth embodiment, configurations other than omission of the color conversion layer may be similar to those of any one of the first embodiment to the fifth embodiment. In the example of FIG. 20, a first light emitting layer 14 is configured as illustrated in FIG. 3A and has a red light emitting layer 142R and a green light emitting layer 142G.

In addition, in the example illustrated in FIG. 20, in the display device 10 according to the sixth embodiment, light emission colors of the first subpixel and the second subpixel are the same. The first subpixel and the second subpixel become subpixels (subpixels 101RG1 and 101RG2) that emit light acquired by causing light of the wavelength region of the red color and light of the wavelength region of the green color to face each other. Thus, in this example, the first subpixel and the second subpixel are the subpixels 101RG1 and 101RG2, and a third subpixel becomes a subpixel 101B. In addition, in FIG. 20, although the subpixels 101RG1 and 101RG2 have the light emitting element 104A, both parts of the light emitting elements 104 that correspond to the subpixels 101RG1 and 101RG2 are represented as light emitting elements 104ARG.

### 6-2 Operations and Effects

In the display device 10 according to the sixth embodiment, similar to the display device according to the first embodiment, the third subpixel (the subpixel 101B) is formed to overlap the first subpixel and the second subpixel (the subpixels 101RG1 and 101RG2), and the subpixels 101RG1 and 101RG2 have the first light emitting layer 14. In the display device 10 according to the sixth embodiment, as described below, two-color display can be performed by independently driving three types of the subpixels 101RG1, 101RG2, and 101B.

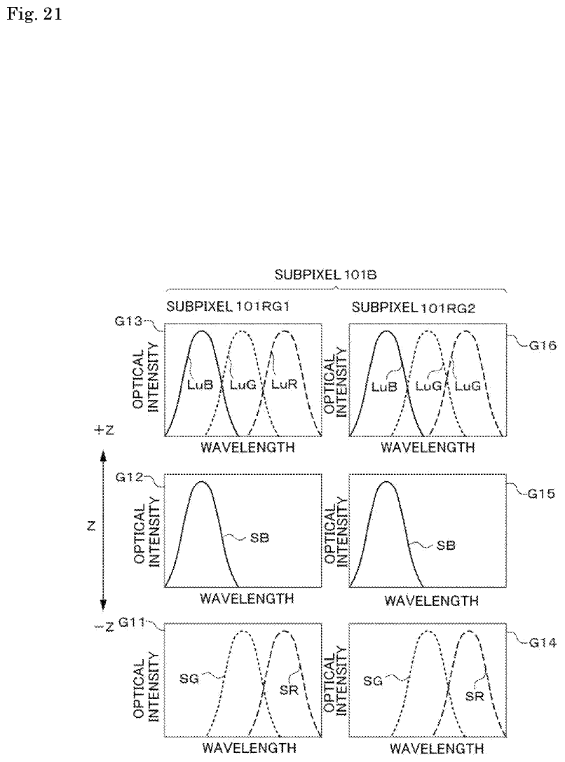

When a voltage is applied between the first electrode 13 and the second electrode 15 corresponding to the subpixel 101RG1, a state in which an electric field is applied to a part of the first light emitting layer 14 that corresponds to the first subpixel (the subpixel 101RG1) is formed. At this time, light is generated from the first light emitting layer 14. As illustrated in a graph G11 illustrated in FIG. 21, this light becomes light acquired by combining light having a spectrum distribution SR in the wavelength region of the red color and light having a spectrum distribution SG in the wavelength region of the green color. At this time, in the subpixel 101RG1, light generated in the first light emitting layer 14 is transferred in the +Z direction in FIG. 21 and is extracted. Thus, light extracted from the first light emitting layer 14 in the subpixel 101RG1 becomes light acquired by causing light having a spectrum distribution LuR in the wavelength region of the red color and light having a spectrum distribution LuG in the wavelength region of the green light to face each other (a graph G13 illustrated in FIG. 21). FIG. 21 is a diagram for describing a light extracting mechanism of the display device according to the sixth embodiment. In FIG. 21, in each layer of the display device 10, from the −Z side, a spectrum distribution diagram (graphs G11 and G14) of light generated from the first light emitting layer 14 configuring the subpixels 101RG1, 101RG2, and 101B, a spectrum distribution diagram (graphs G12 and G15) of light generated from the second light emitting layer, and a spectrum distribution diagram (graphs G13 and G16) of light extracted from the subpixels 101R, 101G, and 101B are illustrated.

In addition, when a voltage is applied between the first electrode 13 and the second electrode 15 corresponding to the subpixel 101GR2, a state in which an electric field is applied to a part of the first light emitting layer 14 that corresponds to the subpixel 101RG2 is formed. At this time, in the subpixel 101RG2, similar to the description of the subpixel 101RG1, from the first light emitting layer 14, light acquired by combining light having a spectrum distribution SR in the wavelength region of the red color and light having a spectrum distribution SG in the wavelength region of the green color is generated (a graph G14 illustrated in FIG. 21). At this time, in the subpixel 101RG2, light generated in the first light emitting layer 14 is transferred in the +Z direction in FIG. 21 and is extracted. Thus, light extracted from the first light emitting layer 14 in the subpixel 101RG2 becomes light acquired by causing light having a spectrum distribution LuR in the wavelength region of the red color and light having a spectrum distribution LuG in the wavelength region of the green light to face each other (a graph G16 illustrated in FIG. 21).

Furthermore, when a voltage is applied between the third electrode 17 and the second electrode 15, a state in which an electric field is applied to the second light emitting layer 16 is formed. At this time, from the second light emitting layer 16, light is generated. This light, as illustrated in graphs G12 and G15 illustrated in FIG. 11, becomes light (blue light) having a spectrum distribution SB in the wavelength region of the blue color. In the subpixel 101B, blue light generated in the second light emitting layer 16 is extracted. In this way, light extracted from the second light emitting layer 16 in the subpixel 101B is occupied with light having a spectrum distribution LuB in the wavelength region of the blue color (graphs G13 and G16 illustrated in FIG. 21).

By being able to individually apply voltages to the first electrode 13 and the third electrode 17, the subpixels 101RG1, 101RG2, and 101B can be caused to individually emit light of a color acquired by combining the red color and the green color and light of the blue color, and thus the display device 10 can perform two-color display for the display area 10A.

In the display device 10 according to the fifth embodiment, as described above, similar to the display device according to the first embodiment, the subpixels 101R and 101G and the subpixel 101B are formed to overlap each other. Thus, under a condition that pitches between pixels are the same, in a case in which the display device 10 according to the first embodiment and a display device in which three color types of subpixels are formed using the paint division method are compared with each other, in the display device 10 according to the fifth embodiment, the light emission area of subpixels can be configured to be large. Thus, according to the display device 10 of the first embodiment, luminance can be improved over that of a conventional display device.

### 6-3 Modified Example

In the display device 10 according to the sixth embodiment, although a case in which the first light emitting layer 14 is configured to generate light acquired by causing light of the wavelength region of the red color and light of the wavelength region of the green color to face each other has been used as an example and a case in which the red light emitting layer 142R and the green light emitting layer 142G are disposed in the first light emitting layer 14 has been described, the configuration of the first light emitting layer 14 is not limited thereto. In the display device 10 according to the sixth embodiment, as described in Modified Example 1 of the first embodiment, the first light emitting layer 14 may be configured as illustrated in FIG. 3B (a modified example). In such a case, the first light emitting layer 14 has a structure in which a hole injection layer 140, a hole transport layer 141, a yellow light emitting layer 142Y, and an electron transport layer 143 are stacked.

The yellow light emitting layer 142Y generates light having a spectrum distribution in both wavelength regions including the wavelength region of the red color and the wavelength region of the green color. In accordance with the first light emitting layer 14 having the yellow light emitting layer 142Y, light acquired by causing light of the wavelength region of the red color and light of the wavelength region of the green color to face each can be extracted.

In the display device 10 according to the modified example of the sixth embodiment, as illustrated in FIG. 22, the first subpixel and the second subpixel are subpixels (subpixels 101Y1 and 101Y2) that emit light of the wavelength region of the yellow color. Thus, in this example, the first subpixel and the second subpixel are the subpixels 101Y1 and 101Y2, and the third subpixel is the subpixel 101B. In FIG. 22, both parts of the light emitting elements 104A that correspond to the subpixels 101Y1 and 101Y2 are referred to as a light emitting element 104AY.

### 7 Application Example

### Electronic Apparatus

A light emitting device according to the present disclosure may be included in various electronic apparatuses. For example, the display device 10 according to one of the embodiments described above (any one of the first embodiment to the sixth embodiment) may be included in various electronic apparatuses.

Particularly, it is preferable that the display devices be included in electronic viewfinder of a video camera or a single-lens reflex camera, a head-mounted display, or the like, which requires high resolution, in which the display devices are used for enlargement near eyes.

### Specific Example 1

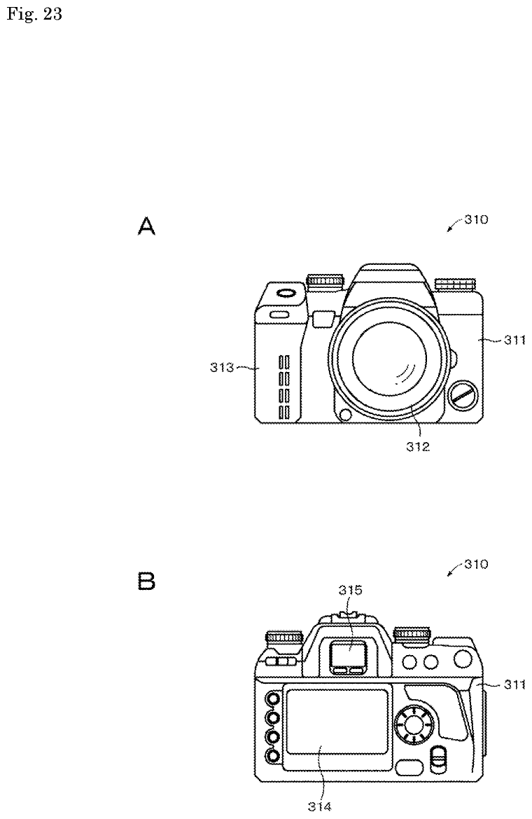

FIG. 23A is a front view illustrating an example of the appearance of a digital still camera 310. FIG. 23B is a rear view illustrating an example of the appearance of the digital still camera 310. The digital still camera 310 is an interchangeable single-lens reflex type camera that has an interchangeable photographing lens unit (interchangeable lens) 312 substantially at the center of the front side of a camera main unit (camera body) 311 and has a grip portion 313 to be held by a photographer on the left side of the front side.

A monitor 314 is provided at a position shifted to the left from the center of the rear side of the camera main unit 311. On the monitor 314, an electronic viewfinder (eyepiece window) 315 is provided. Viewing through the electronic viewfinder 315 allows the photographer to visually recognize an optical subject image guided from the photographing lens unit 312 and determine the composition. The electronic viewfinder 315 may be any one of the display devices 10 according to the foregoing embodiment and modified examples.

### Specific Example 2

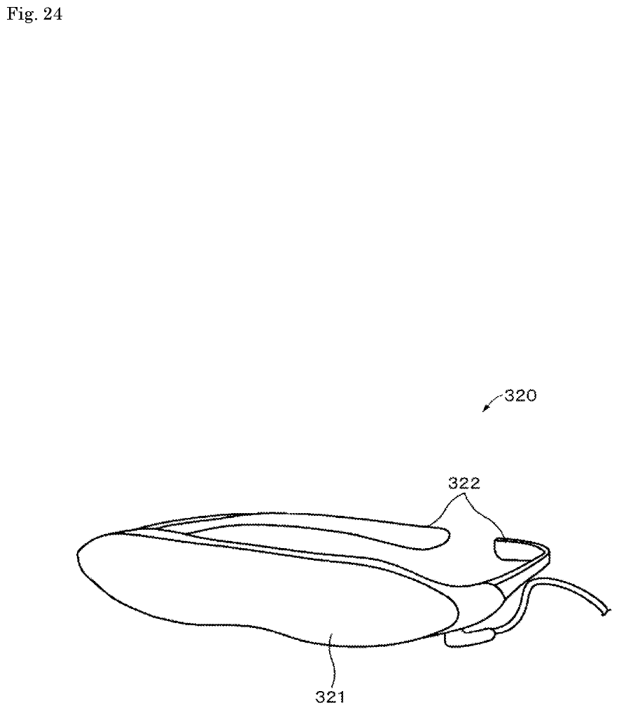

FIG. 24 is a perspective view illustrating an example of the appearance of a head-mounted display 320. The head-mounted display 320 has, for example, ear hooks 322 to be worn on the head of a user. The ear hooks 322 are provided on both sides of an eyeglass-shaped display unit 321. The display unit 321 may be any one of the display devices 10 according to the foregoing embodiment and modified examples.

### Specific Example 3

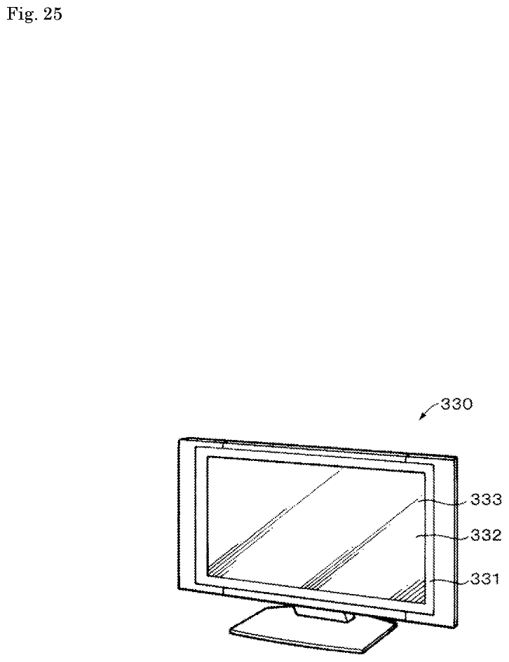

FIG. 25 is a perspective view illustrating an example of the appearance of a television set 330. The television set 330 has, for example, an image display screen part 331 including a front panel 332 and a filter glass 333. The image display screen part 331 is configured with any one of the display devices 10 according to the foregoing embodiment and modified examples.

### 8. Lighting Device

The light emitting device according to the present disclosure has been described in detail in the first embodiment and the sixth embodiment described above using a case in which the light emitting device is a display device as an example. The light emitting device according to the present disclosure is not limited to a display device and may be used as a lighting device. Also in a case in which the light emitting device according to the present disclosure is used as a lighting device, the configurations represented in the first embodiment to the sixth embodiment described above can be employed.

As above, while the display devices according to the first embodiment to the sixth embodiment of the present disclosure and each modified example, the application examples, and the lighting device have been described specifically, the present disclosure is not limited to the display devices according to the first embodiment to the sixth embodiment of the present disclosure and each modified example, the application examples, and the lighting device, and various modifications based on the technical idea of the present disclosure can be performed.

For example, the configurations, the methods, the processes, the shapes, the materials, the numerical values, and the like given in the display devices according to the first embodiment to the sixth embodiment and each modified example described above, the application example, and the lighting device are merely exemplary, and different configurations, methods, processes, shapes, materials, numerical values, and the like may be used as necessary.

The configurations, the methods, the processes, the shapes, the materials, the numerical values, and the like given in the display devices according to the first embodiment to the sixth embodiments and each modified example described above, the application example, and the lighting device can be combined together as long as it does not depart from the concept of the present disclosure.

Unless otherwise specified, one of the materials indicated in the display devices according to the first embodiment to the sixth embodiment and each modified example, the application examples, and the lighting device described above as example may be used alone, or two or more of the materials may be used in combination.

In addition, the present disclosure may have the following constitutions.
(1) A light emitting device including: a first subpixel; and a second subpixel and a third subpixel of which color types are different from that of the first subpixel, in which the first subpixel and the second subpixel have a first light emitting layer emitting light of a predetermined color type, and the third subpixel has a second light emitting layer that is stacked on the first light emitting layer and has a light emission color different from that of the first light emitting layer.
(2) The light emitting device described in (1) described above, further including a color conversion layer converting the light emission color of the first light emitting layer into a color type corresponding to the first subpixel and the second subpixel.
(3) The light emitting device described in (2) described above, in which the color conversion layer is a color filter.
(4) The light emitting device described in (2) described above, in which the color conversion layer is a multi-layer interference layer having a dielectric laminated structure.
(5) The light emitting device described in any one of (1) to (4) described above in which the first subpixel and the second subpixel include a plurality of first electrodes and a second electrode, in which the third subpixel includes a plurality of third electrodes, the plurality of first electrodes are separated in correspondence with the first subpixel and the second subpixel, the third subpixel shares the second electrode with the first subpixel and the second subpixel, and the plurality of third electrodes are separated in correspondence with the third subpixel.
(6) The light emitting device described in any one of (1) to (4) described above, in which the first subpixel and the second subpixel include a plurality of first electrodes and a second electrode, the third subpixel includes a plurality of third electrodes and a fourth electrode, the plurality of first electrodes are separated in correspondence with the first subpixel and the second subpixel, the second electrode is a common electrode that is common to the first subpixel and the second subpixel, and the plurality of third electrodes are separated in correspondence with the third subpixel.
(7) The light emitting device described in (6) described above, in which the first electrodes and the second electrode are stacked with the first light emitting layer interposed therebetween, the third electrodes and the fourth electrode are stacked with the second light emitting layer interposed therebetween, the second electrodes and the third electrode are disposed between the first light emitting layer and the second light emitting layer, and an insulating layer separating the second electrodes and the third electrode are disposed.
(8) The light emitting device described in any one of (1) to (7) described above, in which the first subpixel, the second subpixel, and the third subpixel independently emit light.
(9) The light emitting device described in any one of (1) to (8) described above, in which each of the first subpixel and the second subpixel has a resonator structure causing light of a specific wavelength out of light generated in the first light emitting layer to resonate.
(10) The light emitting device described in any one of (1) to (9) described above, in which the first subpixel and the second subpixel respectively have red and green as light emission colors, and the third subpixel has blue as a light emission color.
(11) The light emitting device described in any one of (1) to (10) described above, in which a light emission area of the third subpixel is larger than any one of a light emission area of the first subpixel and a light emission area of the second subpixel.
(12) An electronic apparatus including the light emitting device described in any one of (1) to (11) described above.

### REFERENCE SIGNS LIST

10 Display device
10A Display area
11 Drive substrate
11A Substrate
12 Insulating layer
12A Opening part
13 First electrode
14 First light emitting layer
15 Second electrode
16 Second light emitting layer
17 Third electrode
18 Color filter
18C Cyan color filter
18M Magenta color filter
19 Multi-layer interference layer
20 Resonator structure
21 Protective layer
22 Third electrode
23 Insulating layer
24 Fourth electrode
25 First relay electrode layer
26 Second relay electrode layer
27 Second contact hole
27A Second contact part
28 First contact hole
28A First contact part
29 Groove part
30A Insulating layer
30B Insulating layer
101 Subpixel
104 Light emitting element
105 Light emitting element
310 Digital still camera
311 Camera main body unit
312 Imaging lens unit
313 Grip part
314 Monitor
315 Electronic viewfinder
320 Head-mounted display
321 Display unit
322 Ear hook part
330 Television set
331 Video display screen unit
332 Front panel
333 Filter glass

1. A light emitting device comprising:
a first subpixel; and
a second subpixel and a third subpixel of which color types are different from that of the first subpixel,
wherein the first subpixel and the second subpixel have a first light emitting layer emitting light of a predetermined color type, and
wherein the third subpixel has a second light emitting layer that is stacked on the first light emitting layer and has a light emission color different from that of the first light emitting layer.

2. The light emitting device according to claim 1, further comprising a color conversion layer converting the light emission color of the first light emitting layer into a color type corresponding to the first subpixel and the second subpixel.

3. The light emitting device according to claim 2, wherein the color conversion layer is a color filter.

4. The light emitting device according to claim 2, wherein the color conversion layer is a multi-layer interference layer having a dielectric laminated structure.

5. The light emitting device according to claim 1,
wherein the first subpixel and the second subpixel include a plurality of first electrodes and a second electrode,
wherein the third subpixel includes a plurality of third electrodes,
wherein the plurality of first electrodes are separated in correspondence with the first subpixel and the second subpixel,
wherein the third subpixel shares the second electrode with the first subpixel and the second subpixel, and
wherein the plurality of third electrodes are separated in correspondence with the third subpixel.

6. The light emitting device according to claim 1,
wherein the first subpixel and the second subpixel include a plurality of first electrodes and a second electrode,
wherein the third subpixel includes a plurality of third electrodes and a fourth electrode,
wherein the plurality of first electrodes are separated in correspondence with the first subpixel and the second subpixel,
wherein the second electrode is a common electrode that is common to the first subpixel and the second subpixel, and
wherein the plurality of third electrodes are separated in correspondence with the third subpixel.

7. The light emitting device according to claim 6,
wherein the first electrodes and the second electrode are stacked with the first light emitting layer interposed therebetween,
wherein the third electrodes and the fourth electrode are stacked with the second light emitting layer interposed therebetween,
wherein the second electrodes and the third electrode are disposed between the first light emitting layer and the second light emitting layer, and
wherein an insulating layer separating the second electrodes and the third electrode are disposed.

8. The light emitting device according to claim 1, wherein the first subpixel, the second subpixel, and the third subpixel independently emit light.

9. The light emitting device according to claim 1, wherein each of the first subpixel and the second subpixel has a resonator structure causing light of a specific wavelength out of light generated in the first light emitting layer to resonate.

10. The light emitting device according to claim 1,
wherein the first subpixel and the second subpixel respectively have red and green as light emission colors, and
wherein the third subpixel has blue as a light emission color.

11. The light emitting device according to claim 1, wherein a light emission area of the third subpixel is larger than any one of a light emission area of the first subpixel and a light emission area of the second subpixel.

12. An electronic apparatus comprising the light emitting device according to claim 1.
